(19) United States
(12) Patent Application Publication
(10) Pub. No.: US 2012/0033392 A1
(43) Pub. Date: Feb. 9, 2012

(54) Modular Junction Box for a Photovoltaic Module

(75) Inventors: Boris Golubovic, San Francisco, CA (US); Mudhafar Hassan-Ali, Petaluma, CA (US); Kaochi Im, Bothell, WA (US); Abhijit Limaye, San Jose, CA (US)

(73) Assignee: TYCO ELECTRONICS CORPORATION, Berwyn, PA (US)

(21) Appl. No.: 13/184,281

(22) Filed: Jul. 15, 2011

Related U.S. Application Data
(60) Provisional application No. 61/372,065, filed on Aug. 9, 2010.

(51) Int. Cl. H05K 7/00

(52) U.S. Cl. 361/752

(57) ABSTRACT

A junction box for electrically connecting a photovoltaic (PV) module to a power distribution system, the PV module having a plurality of conductors for electrically connecting the PV module to the junction box. The junction box includes a housing having a mounting side configured to be mounted on the PV module and a power transfer structure mounted within the housing. The power transfer structure includes a plurality of conductive connectors and a transfer interface. Each conductive connector forms an electrical interface to the PV module. The transfer interface couples the junction box to the power distribution system. The junction box also includes a user-removable control board mounted within the housing. The power transfer structure interfaces with said control board to convey power from the PV module to the control board.

### CROSS-REFERENCE TO RELATED APPLICATION

This application claims priority to U.S. provisional patent application No. 61/372,065 filed Aug. 9, 2010, which is incorporated by reference in its entirety for all purposes.

### BACKGROUND OF THE INVENTION

The subject matter described and/or illustrated herein relates generally to photovoltaic (PV) modules, and more particularly, to a junction box for interconnecting PV modules with a power distribution system.

To produce electricity from solar energy, PV modules include a plurality of PV cells interconnected in series and/or parallel, according to the desired voltage and current parameters. PV cells are essentially large-area semiconductor diodes. Due to the photovoltaic effect, the energy of photons is converted into electrical power within a PV cell when the PV cell is irradiated by a light source, such as sunlight. Within a PV module, the PV cells are typically sandwiched between a transparent panel and a dielectric substrate. The PV cells within the PV module are typically interconnected by an electrically conductive foil, such as a metallic foil. A PV module is also known as a PV panel or a solar panel.

PV modules are often interconnected, in series and/or parallel, to create a PV array. Junction boxes are typically used to electrically connect the PV modules to each other and also connect the PV array to an electrical power distribution system. Conventional junction boxes include a housing that is mounted on the dielectric substrate of the corresponding PV module. The housing includes electrical contacts, referred to herein as housing contacts, that engage the conductive foil to electrically connect the PV module to the junction box. At least one conventional junction box also includes a printed circuit board (PCB). Diodes and other electric circuitry may be installed on the printed circuit board. The conventional diodes include integral heat sinks to help dissipate heat within the junction box.

During assembly, the conductive foil received from the PV module is electrically connected to the junction box by inserting the conductive foil through an opening formed through the dielectric substrate. The conductive foil is then inserted into the junction box and wrapped around the housing contact, which may be a spring clip for example, to electrically connect the PV module to the housing contact. The PCB is then installed such that a clip installed on the PCB, referred to herein as a PCB contact, mates with a respective housing contact. More specifically, during installation of the PCB, inserting the PCB contact into the housing contact causes the conductive foil to deform. The deformed conductive foil forms an electrical path between the housing contact and the PCB contact. Because the conductive foil is disposed between the PCB contact and the housing contact, the combination of the PCB contact and the housing contact causes the foil to deform between the contacts thereby maintaining the foil in a relatively fixed position.

Frequently, opening the junction box is not feasible, as some conventional junction boxes are welded shut or are glued shut with epoxy or are an integral part of the PV module. Therefore, in the event of a failure, such as resulting from a problem on the PCB within the junction box, replacing or upgrading that PCB is often impossible without destroying the junction box and/or the PV module. In instances where the junction box is integral with the PV module, the entire integrated junction box/PV module must be replaced even if the failure is from the PCB within the junction box. In other instances, some junction boxes, even if able to be opened, are fully potted with epoxy or sealant and replacing the PCB would be very difficult due to the need to remove the epoxies or sealants. In yet other instances where the junction box may be more easily opened, to replace or upgrade the PCB, the conventional PCB may be removed from the junction box. However, removing the PCB from such a junction box may cause the foil to become damaged, or dislodged or misaligned from the housing contact. When a new or upgraded PCB is installed, the installer must manually replace or align the foil with respect to the housing contact. The installer must then ensure that the foil remains positioned within the housing contact while simultaneously inserted the PCB contact into the housing contact. However, it is often difficult for the installer to properly align the foil within the housing contact while simultaneously inserting the PCB contact into the housing contact. The foil may also become damaged while either removing or installing the PCB.

These various approaches, if even possible, of replacing a PCB within a junction box for a PV module can be very expensive and involve intensive labor.

### BRIEF DESCRIPTION OF THE INVENTION

In one embodiment, a junction box for electrically connecting a photovoltaic (PV) module to a power distribution system is provided. The PV module has a plurality of conductors for electrically connecting the PV module to the junction box. The junction box includes a housing having a mounting side configured to be mounted on the PV module and a power transfer structure mounted within the housing. The power transfer structure includes a plurality of conductive connectors and a transfer interface. Each of the conductive connectors forms an electrical interface to the PV module. The transfer interface couples the junction box to the power distribution system. The junction box also includes a user-removable control board mounted within the housing, the power transfer structure interfaces with said control board to convey power from the PV module to the control board via the power transfer structure. According to specific embodiments, the control board may be removable from the junction box to be replaced or to provide upgraded features. The control board can also provide a shut-off circuit operable to interrupt power transfer between the PV module and the power transfer structure, or may provide circuitry to adjust an output from the PV module to substantially match a maximum power point for the PV array.

In another embodiment, an electrical isolation device for coupling to at least one PV module is provided. The electrical isolation device includes a junction box and a safety isolation device coupled to the junction box, and the safety isolation device is configured to transmit a communication signal to the junction box. The junction box is configured to operate in a first or second mode based on the communication signal. The communication signal may be sent via a wireless transmission or may be sent over the power line, in various specific embodiments.

### BRIEF DESCRIPTION OF THE DRAWINGS

FIG. 1 is a partially exploded perspective view of an exemplary embodiment of a junction box and photovoltaic (PV) module assembly.

FIG. 2 is an exploded view of the junction box assembly shown in FIG. 1, according to a specific embodiment.

FIG. 3 is a top perspective view of the power transfer board shown in FIG. 2.

FIG. 4 is a bottom perspective view of the power transfer board shown in FIG. 2.

FIG. 5 is a side view of the power transfer board shown in FIG. 2.

FIG. 6 is a top perspective view of the power transfer structure built into the housing, as an alternative embodiment to the power transfer board shown in FIG. 2.

FIG. 7 is a top perspective view of the control board shown in FIG. 2.

FIG. 8A is a side view of the control board shown in FIG. 2, according to a specific embodiment.

FIG. 8B is a side view of the power transfer board shown in FIG. 2 coupled to the control board shown in FIG. 2.

FIG. 9 is a bottom perspective view of another exemplary control board that may be used with the junction box shown in FIG. 1.

FIG. 10 is a top perspective view of the control board shown in FIG. 9.

FIG. 11 is a schematic illustration of the control board shown in FIG. 9 in a first operational mode.

FIG. 12 is a schematic illustration of the control board shown in FIG. 9 in a second operational mode.

FIG. 13 is a schematic illustration of the control board shown in FIG. 9 in a third operational mode.

FIG. 14 is a schematic illustration of yet another exemplary control board that may be used with the junction box shown in FIG. 1.

FIG. 15 is a schematic illustration of a further exemplary control board that may be used with the junction box shown in FIG. 1.

FIG. 16 is a schematic illustration of another exemplary control board that may be used with the junction box shown in FIG. 1.

FIG. 17 illustrates an exemplary system that may include the junction box and control boards described in FIGS. 1-16.

FIG. 18 illustrates an exemplary system that may include the junction box and control boards described in FIGS. 1-16.

FIG. 19 is a schematic illustration of the control board shown in FIG. 18.

FIG. 20 is a graphical illustration of exemplary MPP's that may be generated by the PV modules shown in FIG. 18.

FIG. 21 is a simplified electrical schematic illustration of a portion of the control board shown in FIG. 18.

FIG. 22 is a simplified electrical schematic illustration of another control board that may be used with the junction box shown in FIG. 1.

### DETAILED DESCRIPTION OF SPECIFIC EMBODIMENTS OF THE INVENTION

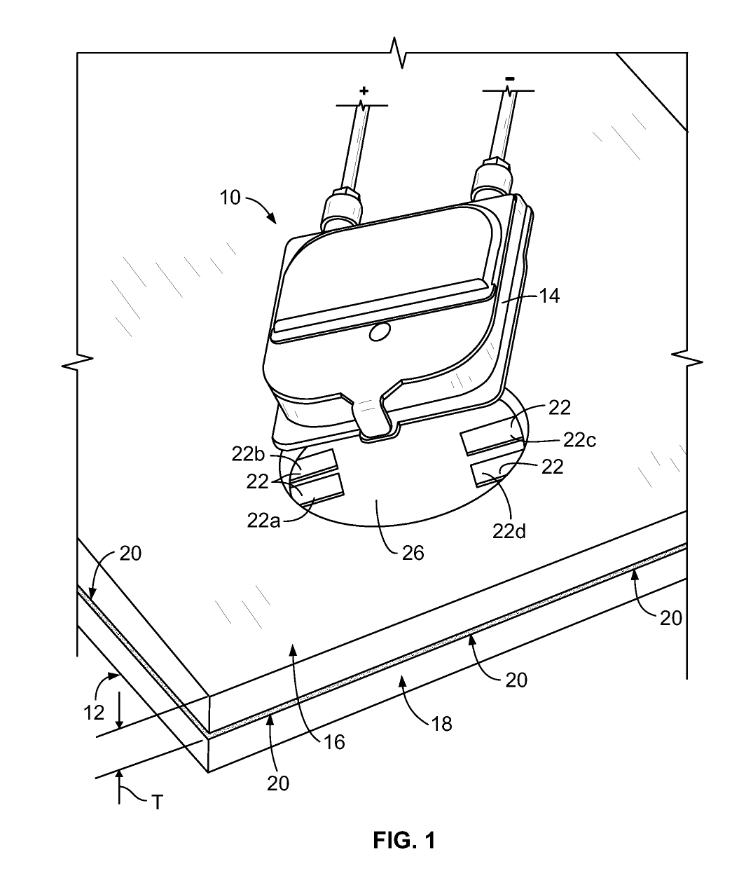

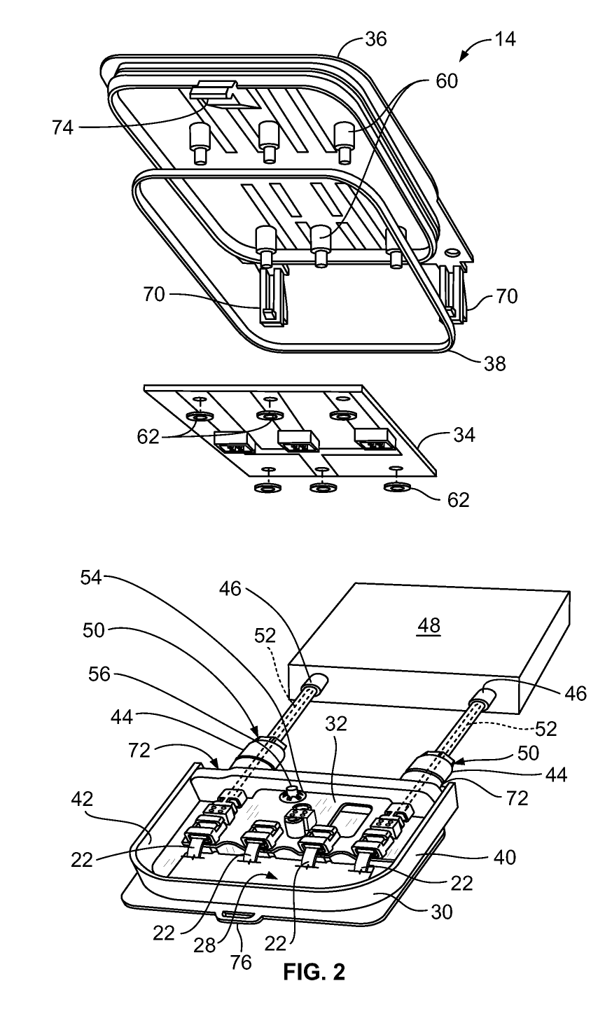

FIG. 1 is a partially exploded perspective view of an exemplary junction box and photovoltaic (PV) module assembly 10. The assembly 10 includes a PV module 12 and a junction box 14. Only a portion of the PV module 12 is shown herein. The PV module 12 includes a dielectric substrate 16, a transparent panel 18, and a plurality of PV cells 20 held between the dielectric substrate 16 and the transparent panel 18. When irradiated by a light source (such as, but not limited to, sunlight and/or the like), the PV cells 20 convert the energy of photons into electrical power. Each PV cell 20 may be any type of PV cell, such as, but not limited to, a thin film PV cell and/or a PV cell fabricated using a material such as a monocrystalline silicon, a polycrystalline silicon, a microcrystalline silicon, a cadmium telluride, and/or a copper indium selenide/sulfide material. The PV cells 20 are electrically interconnected with each other, in series and/or parallel, by an electrical foil conductor 22, such as, but not limited to, a copper foil a zinc foil, and/or the like. The foil conductors 22 are exposed through an opening 26 within the dielectric substrate 16. In the exemplary embodiment, four foil conductors 22, e.g. foil conductor 22a, 22b, 22c and 22d are exposed through the opening 26. However, it should be realized that more, or less, than four foil conductors 22 may be inserted through the opening 26. The junction box 14 also includes an opening 28 (shown in FIG. 2) that receives the foil conductors 22 therethrough. The opening 28 enables the foil conductors 22 to be electrically coupled to various components mounted within the junction box 14 as discussed in more detail below.

The junction box 14 is mounted on the PV module 12 for electrically connecting the PV module 12 to a power distribution system (not shown). The power distribution system conveys electrical power generated by the PV module 12 to an electrical load (not shown), an electrical storage device (not shown), and/or the like. The junction box 14 may also electrically connect the PV module 12 to other PV modules (not shown). For example, a plurality of PV modules may be mechanically and electrically interconnected, in series and/or parallel, to create a PV array (not shown).

The transparent panel 18 of the PV module 12 is transparent to light emitted from the light source. The transparent panel 18 may be transparent to any wavelengths of electromagnetic radiation from any light source. In one embodiment, the transparent panel 18 includes only a single layer. Optionally, the transparent panel 18 may include any number of layers greater than one. Each layer of the transparent panel 18 may be fabricated from the same or different material(s) from other layers of the transparent panel 18. Similarly, although shown as including only one layer, the dielectric substrate 16 may include any number of layers. Each layer of the dielectric substrate 16 may be fabricated from the same or different material(s) from other layers of the dielectric substrate 16.

FIG. 2 is an exploded view of the junction box 14 shown in FIG. 1, according to a specific exemplary embodiment. In the exemplary embodiment, the junction box 14 includes a housing 30, a power transfer board 32, a control board 34, a cover 36, and a gasket 38 configured to be installed between the housing 30 and the cover 36. The housing 30 has an exterior side 40 and an interior side 42. The housing 30 also includes a pair of mating interfaces 44. The mating interfaces 44 are configured to mate with a pair of corresponding mating connectors 46 of an external system 48. The external system 48 may include, for example, a power distribution system, an electrical load, an electrical storage device, or another junction box that is coupled to another PV module.

Each mating interface 44 includes a mating receptacle 50 that receives a conductor 52 of the corresponding mating connector 46 therein. The conductors 52 enable the junction box 14 to be electrically connected to the external system 48. In addition or alternative to the mating receptacle 50, each mating interface 44 of the housing 30 may include a plug (not shown) that is received within a receptacle (not shown) of the corresponding mating connector 46. Although the housing 30 is shown to include two mating interfaces 44, the housing 30 may have any number of mating interfaces 44 for mating with any number of mating connectors 46. In some specific embodiments, the mating interfaces 44 may be covered by heat shrink tubing that provides, for example, ultraviolet resistance, flame retardancy, and additional sealing to preventing moisture from the environment from entering the junction box.

During assembly, the power transfer board 32 has at least one lock washer 54 that receives a respective mounting post 56 therein, or similar means to secure the power transfer board to the housing 30, and to securely couple the power transfer board 32 to the mounting post 56. The foil conductors 22 are electrically coupled to the power transfer board 32. The control board 34 and the cover 36 are then installed by electrically coupling the control board 34 to the power transfer board 32.

More specifically, the cover 36 includes a plurality of mounting posts 60. The control board 34 also includes a plurality of push lock washers 62 that are configured to mate with a respective mounting post 60 on the cover 36 such that the control board 34 is securely coupled to the cover 36.

The cover 36 has a plurality of latch members 70 that each mate with a respective recess 72 on the junction box 14 to retain the cover 36 coupled to the housing 30. The cover 36 also includes at least one arm portion 74 that is disposed on an opposite side of the cover 36. During assembly, the arm portion 74 slides beneath a flange 76 located on the housing 30. The arm portion 74 cooperates with the latch members 70 to maintain the cover 36 securely coupled to the housing 30. The gasket 38 preferably is used to provide a weatherproof seal between the cover 36 and the housing 30.

In the exemplary embodiment, the housing 30 and the cover 36 are fabricated from a substantially rigid, electrical insulating material suitable to receive the power transfer board 32 and the control board 34 therein. More specifically, as discussed above, in the exemplary embodiment, the control board 34 is coupled to the cover 36. Accordingly, the control board 34 is installed and removed in conjunction with the cover 36. During operation, heat generated by the control board 34, and/or the power transfer board 32, is dissipated by transferring the heat from the control board 34 to the cover 36. As such, the cover 36 functions as a heat sink to enable heat generated by the various components installed within the housing 30 to be dissipated through the cover 36. To promote heat dissipation, the cover 36 (or portion thereof) is fabricated from a material that is also thermally conductive. Such thermally conductive materials may include, for example, a thermally conductive epoxy and/or a thermally conductive adhesive. In another example, the cover 36 may be made of a polyphenaline sulfide material having thermally conductive filler, such as RTP 1300x88127 available from RTP Company.

A more detailed description of the power transfer board 32, the control board 34, and a method of coupling the control board 34 to the power transfer board 32 are described below, in accordance with a specific embodiment.

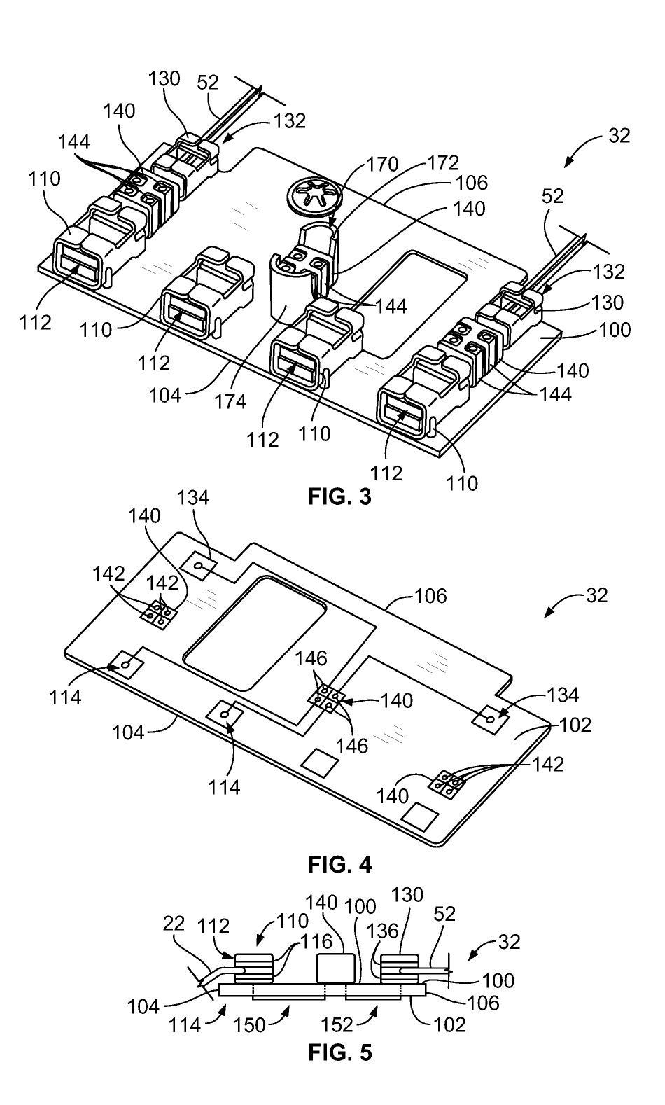

FIG. 3 is a top perspective view of the power transfer board 32 shown in FIG. 2. FIG. 4 is a bottom perspective view of the power transfer board 32 shown in FIG. 2. FIG. 5 is a side view of the power transfer board 32 shown in FIG. 2. In the exemplary embodiment, the power transfer board 32 is a printed circuit board that includes various devices to enable the power transfer board 32 to convey power generated by the PV module 12 to the system 48. The power transfer board 32 also includes various devices to enable the power transfer board 32 to be electrically coupled to the control board 34.

The power transfer board 32 has a first side 100 and an opposing second side 102. As discussed above, in the exemplary embodiment, the power transfer board is a PCB. Accordingly, the first and second sides 100 and 102 are substantially planar such that the first side 100 is substantially parallel to the second side 102. The power transfer board 32 also includes a first edge 104 and an opposing second edge 106. In the exemplary embodiment, the first edge 104 is located proximate to the opening 28 (shown in FIG. 2) to enable the foil conductors 22 to be electrically coupled to the power transfer board 32. The second edge 106 is located proximate to the mating interfaces 44 (also shown in FIG. 2) to enable the external system 48 to be electrically coupled to the power transfer board 32.

The power transfer board 32 includes a plurality of foil connectors 110. Each foil connector 110 is configured to receive a respective foil conductor 22 therein to enable the PV module 12 to be electrically coupled to the power transfer board 32 via the foil conductors 22. Each foil connector 110 includes a foil receptacle 112 and a foil output 114. The foil receptacle 112 is configured to receive a foil conductor 22 therein. The foil output 114 is electrically coupled to a transfer interface 140 that is discussed in more detail below. In one embodiment, the foil connector 110 including the foil receptacle 112 are disposed on the first side 100 of the power transfer board 32 (shown in FIG. 3). The foil receptacle 112 is positioned proximate to the first edge 104. As shown in FIG. 2, the first edge 104 is located proximate to the opening 28 to enable foil conductors 22 inserted through the opening 28 to be easily inserted into the foil receptacles 112. The foil output 114 is disposed on the second side 102 of the power transfer board 32 (shown in FIG. 4). Optionally, the foil output 114 may be disposed on the first side 100.

As shown in FIG. 5, the foil connector 110 also includes a pair of contacts 116 that are configured to physically and electrically couple the foil conductor 22 to the foil connector 110. The pair of contacts 116 are arranged to enable the foil conductor 22 to be inserted and retained within the foil connector 110 approximately parallel to the first side 100. The pair of contacts 116 may be spring-loaded contacts that utilize spring force to retain the foil conductor 22 within the foil connector 110. Optionally, the pair of contacts 116 may be opened and/or closed using a device such as a screw, for example. During assembly, the pair of contacts 116 are separated, either by mechanical pressure on the spring or by optionally loosening the screw. The foil conductor 22 is then inserted between the pair of contacts 116 and the mechanical pressure is released or the screw is tightened such that the foil conductor 22 is retained within and electrically coupled to the foil connector 110. It should be realized that the quantity of foil connectors 110 is determined based on the desired quantity PV modules 12 to be electrically coupled to the power transfer board 32 via the foil conductors 22. FIG. 3 illustrates four foil connectors 110, however, the power transfer board 32 may have fewer than or more than four foil connectors 110.

According to specific embodiments, the power transfer structure or board 32 also includes a plurality of external system connectors 130. As discussed above, the external system 48 may be, for example, a power distribution system, an electrical load, an electrical storage device, or another junction box that is coupled to another PV module. Accordingly, the external system connectors 130 are each configured to receive a system conductor, such as conductor 52, therein. Each system connector 130 includes a system conductor receptacle 132 and a system output 134. The system receptacle 132 is configured to receive the system conductor 52 therein. The system output 134 is configured to couple to the transfer interface 140 that is discussed in more detail below. In one embodiment, the system connector 130 including the system receptacle 132 is disposed on the first side 100 of the power transfer board 32 (shown in FIG. 3), and the system output 134 is disposed on the second side 102 of the power transfer board 32 (shown in FIG. 4). Optionally, the system output 134 may be disposed on the first side 100. Of course, it should be recognized that the system connectors 130 may be provided on the bottom or other part of the housing 30, such as in the cover, according to other embodiments.

As shown in FIG. 5, the system connector 130 also includes a pair of contacts 136 that are configured to physically couple the system conductor 52 to the system connector 130. In the exemplary embodiment, the pair of contacts 136 are arranged to enable the system conductor 52 to inserted and retained within the system connector 130 approximately parallel to the first side 100. In one embodiment, the pair of contacts 136 may be spring-loaded contacts are utilize spring force to maintain the system conductor 52 within the system connector 130. Optionally, the pair of contacts 136 may be opened and/or closed using a device such as a screw, for example. During assembly, the pair of contacts 136 are separated either by mechanical pressure on the spring or by optionally loosening the screw. The system conductor 52 is then inserted between the pair of contacts 136 and the mechanical pressure is released or the screw is tightened such that the system conductor 52 is retained within and electrically coupled to the system connector 130. It should be realized that the quantity of system connectors 130 is determined based on the desired external systems 48 to be electrically coupled to the power transfer board 32 via the system conductors 52 and that although FIG. 3 illustrates two system connectors 130, the power transfer board 32 may have fewer than or more than two system connectors 130. In some embodiments, the system connectors 130 and 132 may be AC, rather than DC, connectors for systems where the DC to AC conversion is performed in the junction box. In some embodiments connectors 130 or 132 may be placed on the control board 34 and omitted from the power transfer board. In some embodiments connectors 72 may be combined into one output point that includes both conductors.

The power transfer board 32 also includes at least one transfer interface 140, according to a specific embodiment. The transfer interface 140 enables electrical signals received at both the foil connectors 110 and the system connectors 130 to be transmitted or conveyed to the control board 34. The transfer interface 140 also enables the control board 34 to mechanically engage and disengage from the transfer interface 140 separate and independent from the electrical connection of the foil conductor 22 to the foil receptacle 112.

The transfer interface 140 may be a receptacle that includes a plurality of transfer inputs 142 and a plurality of transfer outputs 144, according to a specific embodiment. During assembly, the transfer interface 140 is configured to mate with a corresponding device installed on the control board 34. The corresponding device is discussed in more detail below. The transfer interface 140 includes four transfer inputs 142 for transmitting electrical signals from/to the foil connectors 110 and the system connectors 130. Optionally, the transfer interface 142 may include more or less than four inputs 142. The transfer inputs 142 are electrically coupled to the transfer outputs 144 to enable electrical signals received at the transfer inputs 142 to be transmitted or conveyed to the control board 34 via the transfer outputs 144. It should be realized that the quantity of transfer interfaces 140 is determined based on the PV module 12 and external systems 48 to be electrically coupled to the control board 34 via the power transfer board 32. Although FIG. 3 illustrates three transfer interfaces 140, wherein one transfer interface 140 is being utilized and two transfer interfaces 140 are spares, the power transfer board 32 may have fewer than or more than three transfer interfaces 140. Also, it should be recognized that FIG. 3 and FIG. 4 show a cutout within board 32 to accommodate components that may be on control board 34, but such cutouts are optional and would not be needed when components on control board 34 have a sufficiently low profile.

In one embodiment, the transfer inputs 142 are disposed on the second side 102 of the power transfer board 32 (shown in FIG. 4), and the transfer outputs 144 are disposed on the first side 100 of the power transfer board 32 (shown in FIG. 3). Optionally, the transfer inputs 142 may be disposed on the first side 100. As shown in FIG. 5, the transfer interface 140 includes four contacts 146 that are configured to physically couple the transfer interface 140 to both the foil connectors 110 and the system connectors 130 to the transfer interface 140. The foil outputs 114 are electrically coupled to the transfer inputs 142 using a plurality of electrical traces 150 that are formed on the second side 102. Optionally, the foil outputs 114 are electrically coupled to the transfer inputs 142 using hardwires. The system outputs 134 are electrically coupled to the transfer inputs 142 using a plurality of electrical traces 152 that are formed on the second side 102. Optionally, the system outputs 134 may be electrically coupled to the transfer inputs 142 using hardwires.

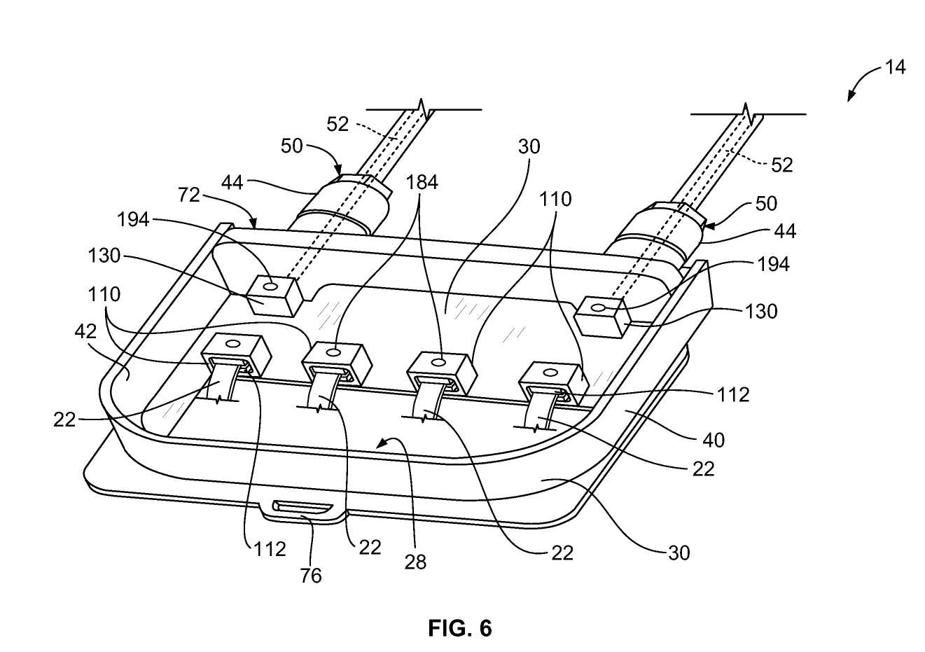

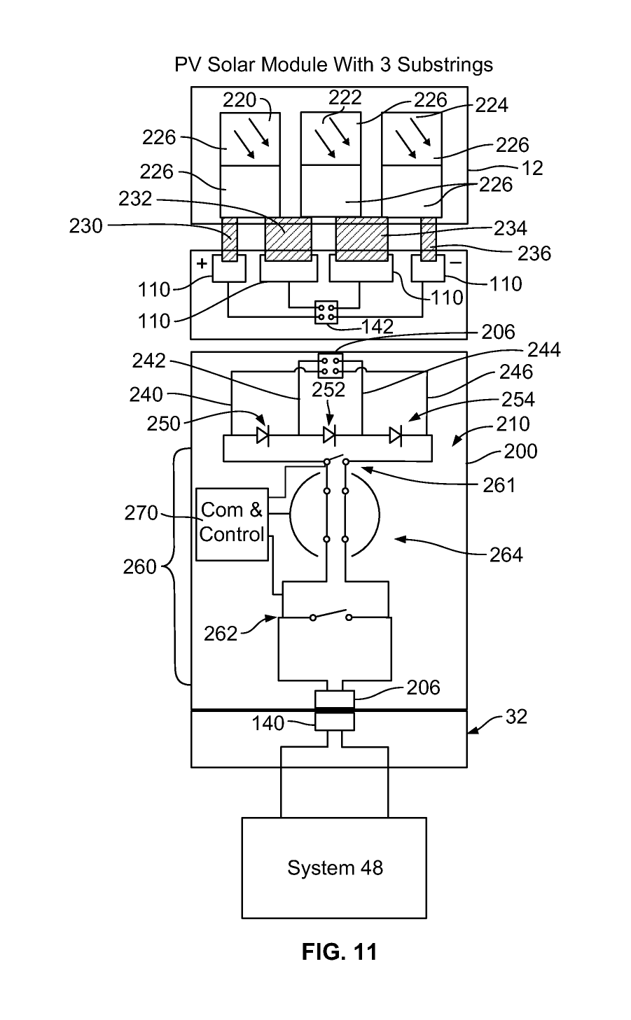

According to other specific embodiments such as shown in FIG. 6, junction box 14 does not include a power transfer board 32 as described in FIGS. 3-5, but instead incorporates a power transfer structure that interfaces with a removable PCB (control board 34) that may be disposed within the cover 36 of the junction box 14. FIG. 6 is a top perspective view of the power transfer structure integrally built into the housing, as an alternative embodiment to the power transfer board shown in FIG. 2. In such embodiments, there are conductive connectors (such as foil connectors 110 with foil receptacles 112) integrally formed within (such as by being molded into) the interior surface of the material of housing 30. These conductive connectors interface to the PV module with conductive leads including but not limited to foil conductors 22. When the cover 36 is fastened to box 14, the conductive connectors can make direct electrical and mechanical connection via transfer interfaces to circuitry formed on the control board 34. Further, system connectors 130 may be integrally formed on the interior surface of housing 30, such that the system conductors 52 can make electrical and mechanical contact with circuitry on the control board 34 when the cover 36 is closed. In these embodiments, the mounting posts 60 of cover 36 may be partially constructed of conductive material and configured so as to be inserted, through vias in control board 34, into transfer interfaces 184, which may be holes formed in conductive connectors 110, and into transfer interfaces 194, which may be holes in system connectors 130. The individual foils may be connected similarly as in other embodiments through clamping, soldering, welding, or gluing and their attachments are not affected by placement or removal of the cover. It should be recognized that the description of FIGS. 11-15, according to specific embodiments, specifies power transfer boards but in other embodiments the power transfer boards may be eliminated by integrating the conductive connectors into the interior surface of housing 30 as discussed above.

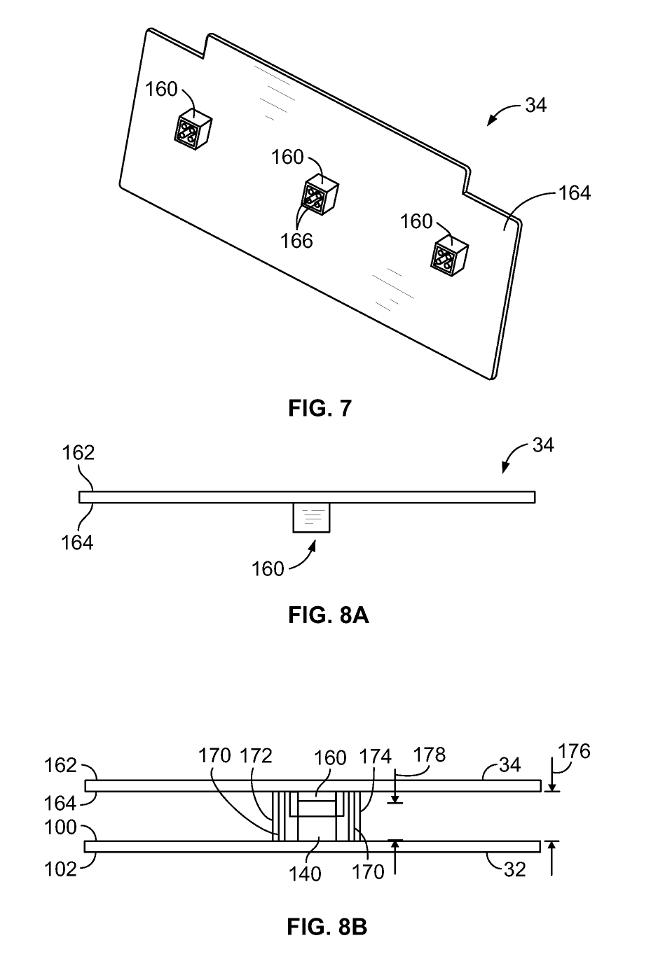

FIG. 7 is a bottom perspective view of the control board 34 shown in FIG. 2. FIG. 8A is a side view of the control board shown in FIG. 2. The control board 34 includes at least one mating connector 160 that mates with the transfer interface 140. The mating connector 160 enables the control board 34 to be both physically and electrically coupled to the power transfer structure (e.g., board 32). The mating connector 160 also enables electrical signals to be transmitted between the control board 34 and the power transfer board 32. Accordingly, the mating connector 160 enables the control board 34 to receive electrical inputs from the external system 48 and the foil conductors 22, via the power transfer board 32, and transmit electrical outputs to the external system 48 and the foil conductors 22, via the power transfer board 32. The control board 34 is configured to modify or otherwise operate on the received electrical signals as is discussed in more detail below.

The control board 34 has a first side 162 and an opposing second side 164. As discussed above, in the exemplary embodiment, the control board 34 is a PCB. Accordingly, the first and second sides 162 and 164 are substantially planar and the first side 162 is substantially parallel to the second side 164. The control board 34 also includes a plurality of mating connectors 160 that is equal to the quantity of transfer interfaces 140 installed on the transfer board 32. Each mating connector 160 is configured to mate with a respective transfer interface 140 to enable the control board 34 to be electrically and mechanically coupled to the power transfer board 32. Each mating connector 160 includes a plurality of pins 166 that are each configured to electrically couple to a respective transfer output 144 in the transfer interface 140. In one embodiment, the mating connector 160 is a female device that is inserted into the transfer interface 140. Optionally, the transfer interface 140 is a female device that is inserted into the mating connector 160.

FIG. 8B is a side view of the control board 34 coupled to the transfer board 32. As discussed above, to facilitate coupling the control board 34 to the transfer board 32, the mating connector 160 on the control board 34 is electrically and mechanically coupled to the transfer interface 140 on the power transfer board 32. To facilitate coupling the mating connector 160 to the transfer interface 140, the transfer board 32 also includes at least one pair of guides 170. As shown in FIGS. 3 and 8B, the pair of guides 170 are mounted to the power transfer board 32. The pair of guides 170 includes at least a first guide 172 that is disposed proximate the transfer interface 140 toward the second edge 106 and a second guide 174 that is disposed proximate to the transfer interface 140 toward the first edge 104. As shown in FIGS. 3 and 8B, a height 176 of the pair of guides 170 is greater than a height 178 of the transfer interface 140 to enable the mating connector 160 to be fully inserted into the transfer interface 140 while maintaining an adequate separation between the control board 34 and the power transfer board 32. The shape of the pair of guides 170 enables an installer to initially place the mating connector 160 proximate to the transfer interface 140 before mating the two together.

A technical effect of the junction box 14 described herein is to provide a junction box that is configured to mount to a PV module. The junction box is upgradeable without modifying the electrical connections between the junction box and the PV module and also without modifying the electrical connections between the junction box and the external system. The electrical connections between the junction box and both the PV module and the external system are made on the power transfer structure, such as for example a power transfer board. The outputs from the power transfer board are conveyed to the control board via the transfer interface and the mating connector. The mating connector on the control board enables the control board to be removed or replaced from the junction box without disturbing any of the electrical connections between the junction box and both the PV module and the external system. Accordingly, the junction box may be upgraded by removing the control board and replacing the control board with another control board that has additional features without modifying the connections between the power transfer board and the PV module. Additionally, the junction box cover, with the attached control board, may be replaced with a new or different junction box cover that includes a new or different control board connected thereto. The junction box described herein thus functions as a universal junction box that enables solar module manufacturers to produce one type of PV modules with ‘universal’ junction boxes that can later be customized to a desired configuration. In some embodiments the control board may be removable but not an integral part of the cover, which cover may be removed without affecting the functionality of the circuit—the cover is opened in the first step, whereas the control board can be removed separately for repair or replacement.

For example, the control board described herein may be modified to include a circuit protection module having bypass diode functionality and/or additional over-voltage and over-current protection components. The junction box cover is fabricated from a thermally conductive material and functions as a heat sink to dissipate heat generated by both the power transfer board and the control board. The control board may also be configured to perform circuit protection functions, communication functions, and other functionalities. Such additional functionalities may include, for example, modifying the control board to accept a micro-inverter (DC to AC converter with maximum power point tracking, optional communication features, and similar functionalities), such as described below. A conventional junction box may be upgraded during manufacturing or field-modified to produce the exemplary junction box described herein.

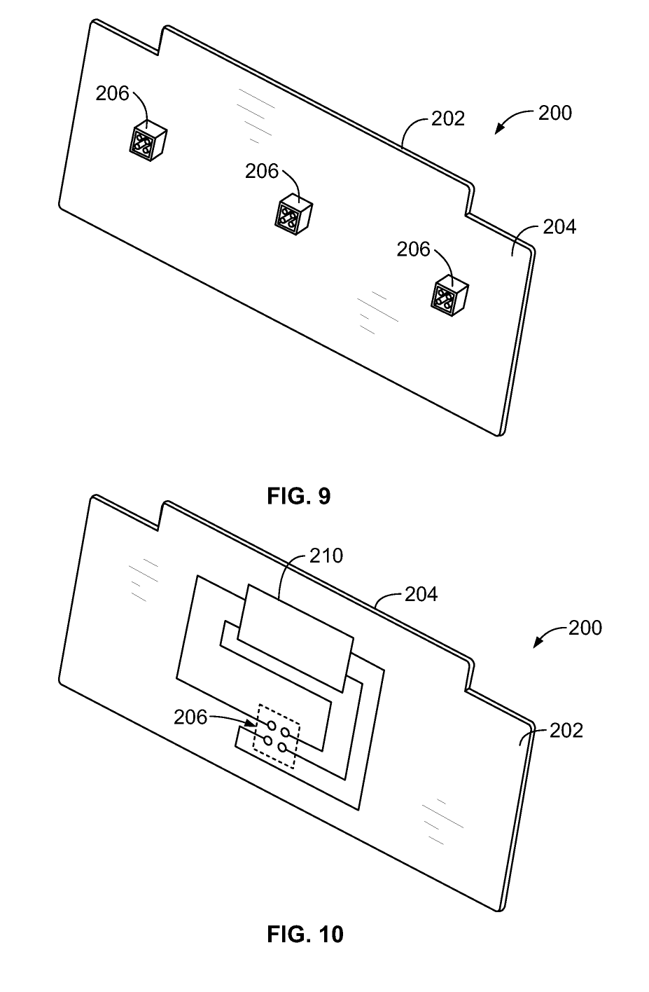

FIG. 9 is a bottom perspective view of an exemplary control board 200 that may be coupled to the power transfer structure or board 32 shown in FIG. 1. FIG. 10 is a top perspective view of the exemplary control board 200. As shown in FIG. 9, the control board 200 has a first side 202 and an opposing second side 204. In the exemplary embodiment, the control board 200 is a PCB. Accordingly, the first and second sides 202 and 204 are substantially planar and the first side 202 is substantially parallel to the second side 204. The control board 200 also includes a plurality of mating connectors 206 that is equal to the quantity of transfer interfaces 140 installed on the transfer structure or board 32.

Each mating connector 206 is installed on the second side 204 to enable the control board 200 to be electrically and mechanically coupled to the power transfer structure as discussed above with respect to the control board 34. For simplicity, only one mating connector 206 is shown in FIG. 10. However, it should be realized that the junction box 14 may include a plurality of mating connectors 206. The combination of the transfer interfaces 140 (shown in FIG. 2) and the mating connectors 206 enable the outputs from the foil connectors 110, on the power transfer structure or board 32, to be conveyed to the control board 200 via the transfer interfaces 140 and the mating connectors 206. Additionally, the outputs/inputs from the system outputs 134 (shown in FIG. 2) are conveyed to the control board 200 via the transfer interfaces 140 and the mating connectors 206.

The control board 200 also includes a PV module shut-off circuit 210 that is installed on the first side 202. The circuit 210 is electrically coupled to at least one of the mating connectors 206 such that the circuit 210 receives electrical signals from both the external system 48 and the PV module 12 via the system connectors 130 and the foil connectors 110, respectively (both shown in FIG. 3). During operation, the shut-off circuit 210 is operable to turn off the PV module 12 when the PV module 12 has been determined to be defective. Additionally, the shut-off circuit 210 is operable to turn off the PV module 12 based on an electrical demand of the system, and/or environmental conditions such as temperature, water ingress, etc., for example.

FIG. 11 is a simplified schematic illustration of the shut-off circuit 210 coupled to the PV module 12 and the system 48 via the power transfer structure or board 32, according to a specific embodiment. In this embodiment, the PV module 12 includes at least three strings of cells, e.g. a string 220, a string 222 and a string 224. Each string 220, 222 and 224 includes a plurality of cells 226 that are electrically coupled in series. Moreover, in this embodiment, the strings 220, 222 and 224 are electrically coupled together in series. Accordingly, the PV module 12 has four foil conductors 230, 232, 234 and 236 that are exposed through the opening 26 within the dielectric substrate 16 (shown in FIG. 1). Additionally, the junction box 14 includes four foil connectors 110 (shown in FIG. 3) for receiving the foil conductors 230, 232, 234 and 236 therein. The electrical signals conveyed from the four foil conductors 230, 232, 234 and 236 are conveyed to the control board 200, via the power transfer board 32 as discussed above. Accordingly, the control board 200 includes four conductors or traces 240, 242, 244 and 246 that electrically couple the shut-off circuit 210 to each respective foil conductor 230, 232, 234 and 236 via the mating connector 206.

The shut-off circuit 210 includes at least one diode (often three diodes 250, 252 and 254) installed on the control board 200. Optionally, the diodes 250, 252 and 254 may be installed on the power transfer board 32 shown in FIG. 2 according to another embodiment. If there are three diodes the first diode 250 is electrically coupled between the first and second traces 240 and 242, and as such, is electrically coupled between the input and output of the first string 220. The second diode 252 is electrically coupled between the second and third traces 242 and 244, and as such, is electrically coupled between the output of the first string 220/input of the second string 222 and the output of the second string 222. The third diode 254 is electrically coupled between the third and fourth traces 244 and 246, and as such, is electrically coupled between the output of the second string 222/input of the third string 224 and the output of the third string 224. As shown in FIG. 11, the trace 240 is the input to the PV module 12 and is therefore coupled to the input of the first string 220. The trace 246 is the output from the PV module and is therefore coupled to the output of the third or final string 224 in the PV module 12.

The shut-off circuit 210 further includes a three-stage relay 260. The three-stage relay 260 includes a relay 261, a primary relay 262 and a secondary relay 264 that is coupled in series with the primary relay 262. The relay 261 and the secondary relay 264 are each coupled between the trace 240 and the trace 246 and are therefore electrically coupled between the input and outputs of the PV module 12. The outputs from the secondary relay 264 are coupled to the inputs of the primary relay 262. The outputs from the primary relay 262 are also electrically coupled to the system 48. During operation, the three-stage relay 260 is operable to enable voltage and current to be conveyed from the PV module 12 to the system 48 via the control board 200. Additionally, the shut-off circuit 210 is configured to electrically isolate the PV module 12 from the system 48.

In the exemplary embodiment, the PV module 12 is configured to be electrically coupled in series with a string of other PV modules (not shown). For example, the PV module 12 may be coupled in series with nine other PV modules (e.g. system 48 represents nine PV modules coupled in series). In the exemplary embodiment, each PV module 12 may generate 60 Volts and an associated current. Accordingly, the PV module array (ten PV modules) may generate approximately 600 Volts DC and an associated current. It should be realized that 600 Volts is exemplary and that an array of PV module may generate more or less than 600 Volts. For example, an array of PV modules may generate 1000 Volts or more.

During operation, each junction box 14 is exposed to the cumulative voltage generated by the entire system 48, e.g. approximately 600-1000 Volts DC. To perform maintenance or repair on an individual PV module, such as PV module 12, the maintenance personnel is required to electrically isolate the PV module 12 from the system 48. Conventional PV modules require personnel to electrically “break” the circuit between the PV module 12 and the system 48 using a conventional switch. However, when opening the conventional switch to break the circuit, an electrical arc may occur that may be hazardous to personnel. The control board 200 described herein enables an operator to “break” the electrical connection between the system 48 and the PV module 12 such that the operator is not exposed to an electrical arc that is equivalent to the voltage of the entire electrical system, e.g. 600-1000 Volts.

In a first operational mode, shown in FIG. 11, the shut-off circuit 210 enables DC voltage and current to be conveyed from the PV module 12 to the system 48 via the control board 200. More specifically, in the first or normal operational mode, the shut-off circuit 210 is configured such that the relay 261 and the primary relay 262 are each “open” and the secondary relay 264 is “closed”. As shown in FIG. 11, when the relay 261 and the primary relay 262 are “open”, voltage and current generated by the PV module 12 are conveyed from the PV module 12, through the secondary relay 264 to the system 48, via the power transfer board 32 as discussed above.

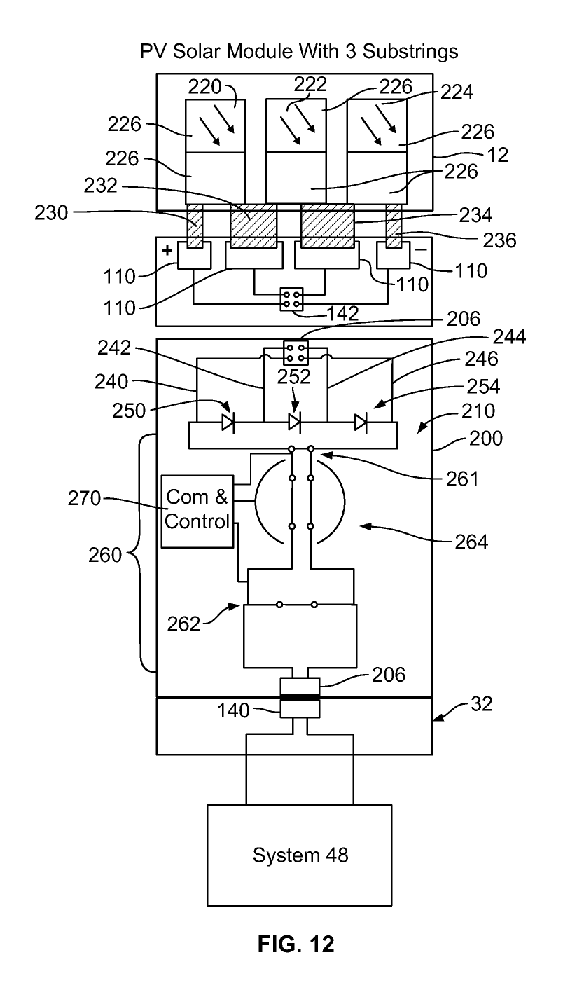

To electrically isolate the PV module 12 from the system 48, the shut-off circuit 210 is also configured to operate in a second operational mode shown in FIG. 12. More specifically, if the operator desires to electrically isolate the PV module 12 from the system 48, the operator initially causes the relay 261 to close creating a short circuit across the cross the relay 262 creating a short circuit across the primary relay 262. The operator may then close the primary relay 262 to create a short circuit within the junction box 14. In the second operational mode, the relay 261 and both the primary and secondary relays 262 and 264 are closed such that the voltage and current generated by the PV module 12 are not conveyed to the system 48. Moreover, in the second operational mode, current generated by the PV module 12 is still being channeled between the PV module 12 and the junction box 14. Therefore, in the second operational mode, the junction box 14 “sees” only the voltage and current generated by the PV module 12 and does not “see” and voltage or current that is generated by any of the other PV modules in the string that represents system 48.

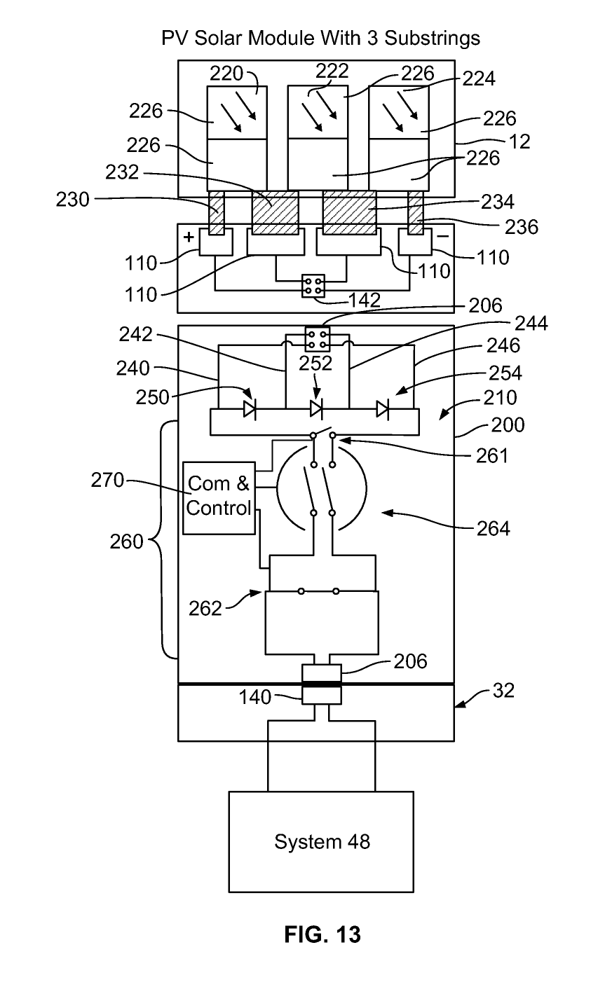

To electrically isolate the PV module 12 from the junction box 14, the shut-off circuit 210 is also configured to operate in a third operational mode shown in FIG. 13. In the third operational mode, the operator causes the secondary relay 264 to open. The relay 261 is then opened. Accordingly, the voltage across the primary relay 262 is approximately 0 Volts thereby reducing any arcs across the primary relay 262. During operation, the relay 261 generates a relatively small voltage across the primary relay 262. In the exemplary embodiment, the relay 261 is a MOSFET that facilitates reducing the generation of an electrical arc. Accordingly, in the third operational mode, the primary relay 262 is closed and the relay 261 and the secondary relay 264 are both open. The third operational mode is also referred to herein as the “safe state”. In the safe state, the current generated by the PV module 12 is not being circulated through the junction box 14. It should be realized that, because the PV module 12 is isolated from the system 48 by closing the relay 261 and the primary relay 262 in the second operational mode, such that when the operator opens the secondary relay 264 to isolate the junction box 14, the junction box 14 only sees the voltage generated by the single PV module 12, e.g. approximately 60 Volts in the exemplary embodiment. Therefore, the arc that may be created by opening the secondary relay 264 is significantly less powerful than an arc created by opening a conventional switch. Moreover, because, the junction box 14 sees only the voltage from the single PV module 14, the junction box 14 may utilize electrical components that suitable for a lower voltage application, thus reducing the overall cost of the junction box 14. To reconnect the PV module 12 to the system 48, the secondary relay 264 is initially closed. The primary relay 262 is then opened such that the junction box 14 is again operating in the first operational mode as shown in FIG. 11.

In the exemplary embodiment, the control board 200 also includes a communication and control device 270 that is electrically coupled to at least the primary and secondary relays 262 and 264. During operation, the communication and control device 270 is configured to receive an input either locally at the junction box 14 or from a remote location, and operate the primary and secondary relays 262 and 264 based on the received input. In one embodiment, the communication and control device 270 may be hard-wired to the remote location and receive an input over the hard-wired line. Optionally, the communication and control device 270 is configured to receive a wireless transmission from the remote location.

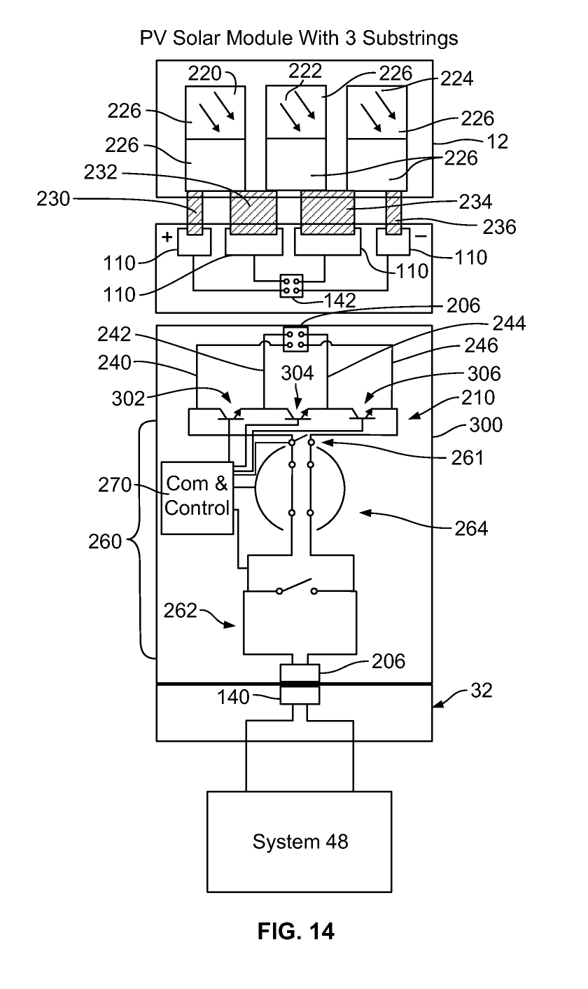

FIG. 14 is a schematic illustration of another exemplary control board 300 that may be used with the junction box shown in FIG. 1. The control board 300 is substantially similar to the control board 200 shown in FIGS. 9-13. In this embodiment, the diodes of control board 200 in circuit 210 have been replaced with electrical switches to enable an operate to electrically isolate a single string in the PV module 12. For example, the operator may electrically isolate either string 220, 222, and or 224 from transmitting voltage and current to the system 48. The switches described herein may be used in combination with or separately from the primary and secondary relays 262 and 264 discussed above. In the exemplary embodiment, the control board 300 is a PCB that is configured to mate with the power transfer board 32 also discussed above.

The control board 300 includes a first switch 302, a second switch 304 and a third switch 306 that in the exemplary embodiment are installed on the control board 300. Optionally, the three switches 302, 304 and 306 may be installed on the power transfer board 32 shown in FIG. 2. The switches 302, 304 and 306 may be any type of electrical switch that is capable of interrupting the flow of electricity. In the exemplary embodiment, the switches 302, 304 and 306 are thin-film transistors (TFT) such as Field-Effect Transistors (FET), Metal Oxide Semiconductors (MOSFET)'s, for example.

The first switch 302 is electrically coupled between the first and second traces 240 and 242, and as such, is electrically coupled between the input and output of the first string 220. The second switch 304 is electrically coupled between the second and third traces 242 and 244, and as such, is electrically coupled between the output of the first string 220/input of the second string 222 and the output of the second string 222. The third switch 306 is electrically coupled between the third and fourth traces 244 and 246, and as such, is electrically coupled between the output of the second string 222/input of the third string 224 and the output of the third string 224. The first switch 302, second switch 304 and third switch 306 are electrically coupled to the communication and control device 270. The communication and control device 270 is configured to receive an input either locally at the junction box 14 or from a remote location, and operate the first switch 302, second switch 304 and third switch 306 based on the received input. In one embodiment, the communication and control device 270 may be hard-wired to the remote location and receive an input over the hard-wired line. Optionally, the communication and control device 270 is configured to receive a wireless transmission from the remote location.

During operation, the switches 302, 304 and/or 306 may be operated by bypass each individual string 220, 222 and/or 224, respectively. Isolating an individual string or a group of strings enables an operator to control and/or bypass under-performing strings and also enables the operator to monitor the voltage and/or current generate by the individual string. For example, the operator may modify the impedance of the switches 302, 304 and/or 306 by modifying the voltage signal transmitted to the switches. Because, in the exemplary embodiment, the switches 302, 304 and/or 306 are MOSFETs, in a specific embodiment, modifying the voltage controlling the MOSFET enables the operator to operate each string at various voltage and current outputs. Accordingly, the switches 302, 304 and/or 306 may be operated to identify any mismatch in the maximum power point tracking (MPPT) voltage and current and to determine the overall health of each string in the PV module 12.

The information from each string may then be transmitted to a monitoring system, such as communication and control device 270, for example to enable the operator to identify underperforming or non-operational strings and also determine if a string should be repaired or replaced. Information from the switches 302, 304 and/or 306 may also be utilized by the communication and control device 270 to determine the operational mode of the PV module, for example, whether the PV module is operating in the normal mode or the safe state.

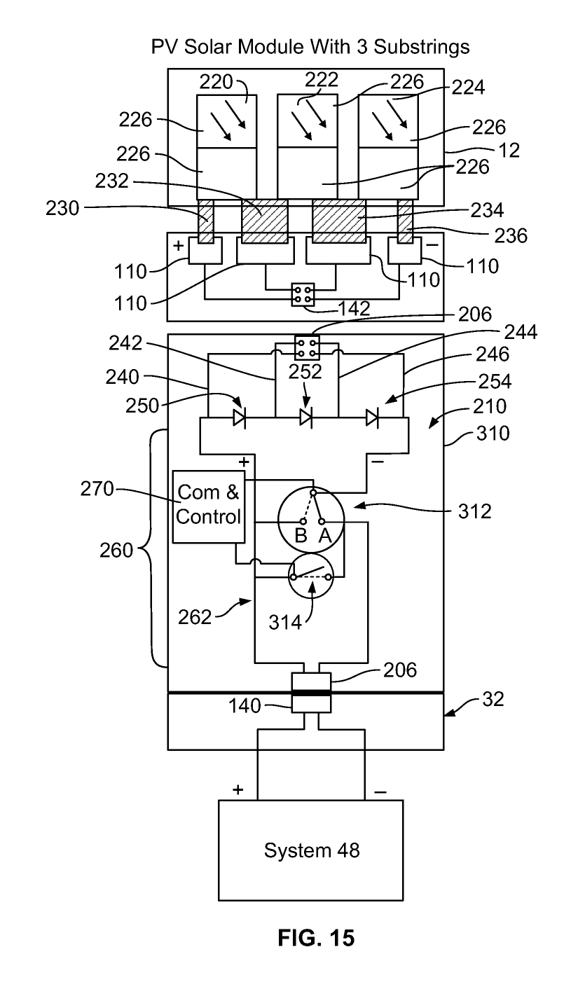

FIG. 15 is a schematic illustration of another exemplary control board 310 that may be used with the junction box shown in FIG. 1. The control board 310 is substantially similar to the control board 200 shown in FIGS. 9-13. In the exemplary embodiment, the control board 310 is a PCB that is configured to mate with the power transfer board 32 also discussed above.

The control board 310 includes a first switch 312 and a second switch 314 that in the exemplary embodiment are installed on the control board 310. Optionally, the switches 312 and 314 may be installed on the power transfer board 32 shown in FIG. 2. The switches 312 and 314 may be any type of electrical switch that is capable of interrupting the flow of electricity. In the exemplary embodiment, the switches 312 and 314 are electrical/mechanical relays. As shown in FIG. 15, the switches 312 and 314 are electrically coupled to the communication and control device 270. The communication and control device 270 is configured to receive an input either locally at the junction box 14 or from a remote location, and operate the switches 312 and 314 based on the received input. In one embodiment, the communication and control device 270 may be hard-wired to the remote location and receive an input over the hard-wired line. Optionally, the communication and control device 270 is configured to receive a wireless transmission from the remote location. The control board 310 described herein enables an operator to “break” the electrical connection between the system 48 and the PV module 12 such that the operator is not exposed to an electrical arc that is equivalent to the voltage of the entire electrical system, e.g. 600-1000 Volts.

In a first operational mode, shown in FIG. 15, the switch 312 is connected to the terminal “A” and the switch 314 is open. In this operational mode, the voltage and current generated by the PV module 12 are conveyed from the PV module 12 to the system 48, via the power transfer board 32 as discussed above.

In a second operational mode, to bypass the PV module 12 from the system 48, the switch 314 is closed to create a short circuit across the PV module 12. The switch 312 is then moved from position A to position B. After, the switch 312 is in position B, the switch 314 is then re-opened. More specifically, if the operator desires to electrically isolate the PV module 12 from the system 48, the operator initially causes the switch 314 to close creating a short circuit across the cross the switch 314. The operator may then move the switch 312 to the B position and reopen the switch 314. Therefore, in the second operational mode, the junction box 14 “sees” only the voltage and current generated by the PV module 12 and does not “see” and voltage or current that is generated by any of the other PV modules in the string that represents system 48.

To reconfigure the PV module 12 from the second operational mode back to the first operational mode, the operator initially closes switch 314. The switch 312 is then moved from the B position back to the A position and the switch 314 is again re-opened. The control board shown in FIG. 15 includes only two relays or switches. Thus the control board 310 has fewer components which reduces the cost of fabricating the control board. Additionally, control board 310 is relatively small in size thus easily retrofittable in a conventional junction box. Moreover, if there is a failure of the switch 312, the switch 314 may perform the functionality of the switch 312. The control board 310 also substantially eliminates any electrical arcing that may occur when electrically isolating the PV module.

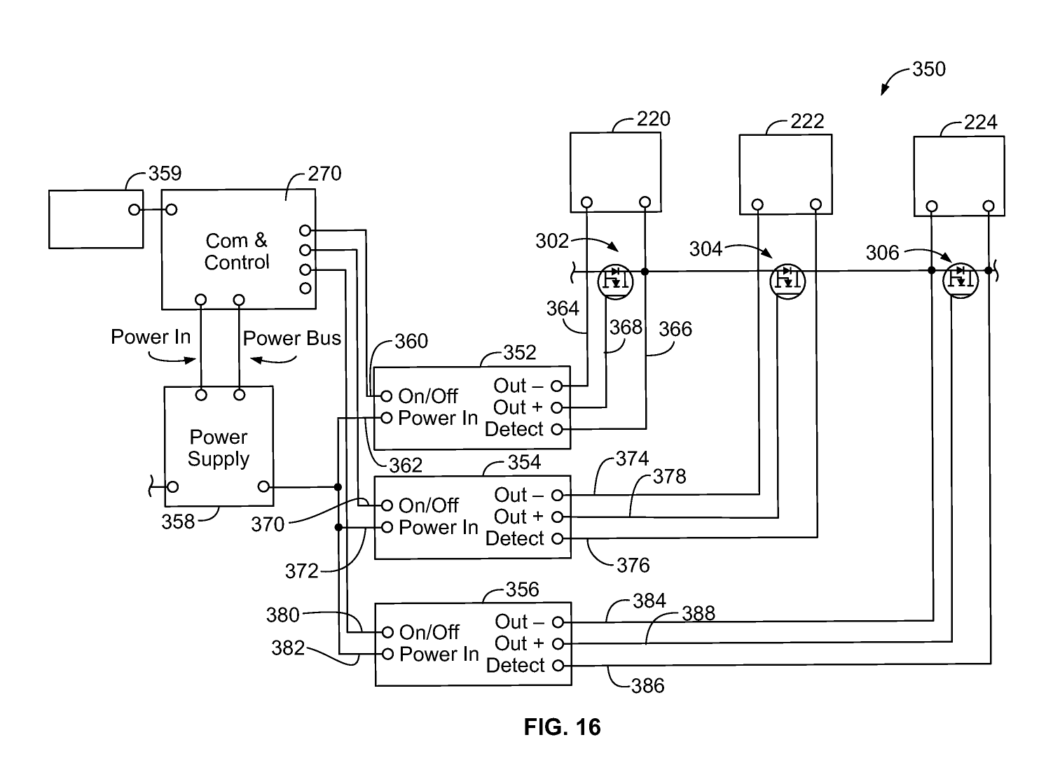

FIG. 16 is a schematic illustration of another exemplary control board 350 that may be used with the junction box shown in FIG. 1. The control board 350 is substantially similar to the control board 300 shown in FIG. 14. In this embodiment, the first switch 302, the second switch 304, and the third switch 306 are each electrically coupled to a respective DC/DC converter. For example, the first switch 302 is electrically coupled to a first isolation power converter 352, the second switch 304 is electrically coupled to a second isolation power converter 354, and the third switch 306 is electrically coupled to a third isolation power converter 356. The control board 350 also includes a processor, such as the communication and control device 270 described above, and a power supply 358. In the exemplary embodiment, the processor 270 is coupled to a user interface 359 that enables a user to input commands to the processor 270 for controlling the operation of the control board 350. The communication and control device 270 is configured to receive an input either locally at the junction box 14 or from a remote location, and operate the first switch 302, the second switch 304 and the third switch 306 based on the received input. In one embodiment, the communication and control device 270 may be hard-wired to the remote location and receive an input over the hard-wired line. Optionally, the communication and control device 270 is configured to receive a wireless transmission from the remote location.

As shown in FIG. 16, the isolation power converter 352 includes a processor input 360 that is received from the processor 270 and a power supply input 362 that is received from the power supply 358. The isolation power converter 352 also includes two inputs from the string 220. Specifically, an input 364 is electrically coupled to the negative side of the string 220 and an input 366 is coupled to a positive side of the string 220. The isolation power converter 352 also includes an output 368 that is electrically coupled to the switch 302.

Similar to the isolation power converter 352, the isolation power converter 354 includes a processor input 370 that is received from the processor 270 and a power supply input 372 that is received from the power supply 358. The isolation power converter 354 also includes two inputs from the string 222. Specifically, an input 374 is electrically coupled to the negative side of the string 222 and an input 376 is coupled to a positive side of the string 222. The isolation power converter 354 also includes an output 378 that is electrically coupled to the switch 304.

Additionally, the isolation power converter 356 includes a processor input 380 that is received from the processor 270 and a power supply input 382 that is received from the power supply 358. The isolation power converter 356 also includes two inputs from the string 224. Specifically, an input 384 is electrically coupled to the negative side of the string 224 and an input 386 is coupled to a positive side of the string 224. The isolation power converter 356 also includes an output 388 that is electrically coupled to the switch 306.

During operation, the switches 302, 304 and/or 306 may be operated to bypass each individual string 220, 222 and/or 224, respectively. Isolating an individual string or a group of strings enables an operator to control and/or bypass under-performing strings and also enables the operator to monitor the voltage and/or current generated by the individual strings. As discussed above, the various strings forming the PV module 12, e.g. strings 220, 222, and/or 224, may be electrically isolated from the array by shorting across the two output terminals from the string using the appropriate switches. For example, to isolate the string 220, the switch 302 is powered in the open position. In the exemplary embodiment, the FET coupled to each string is activated by a separate gate voltage that is supplied from the respective isolation power converter. When a voltage signal is applied to the FET, the FET is “open” and a short circuit (or shunt) is created across the string. However, when the power signal from the DC/DC converter is terminated, the FET is in the closed position and the string is not short circuited. The operation of the various components is now explained with respect to the string 220 and the FET 302. However, it should be realized that the other strings, e.g. strings 222 and 224 may be electrically isolated in the same manner as string 220.

In one mode of operation, the string 220 is not electrically isolated. More specifically, during normal operation, when a user desires that electrical power generated by the string 220 be transmitted to an end user, the switch 302 is “closed” or powered. In the exemplary embodiment, the power is transmitted from the power supply 358 to the isolation power converter 352. Additionally, a command is sent via the input 360 to turn the isolation power converter 352 “ON”. In the ON state, the isolation power converter 352 is enabled to receive an electrical input at the input 362 and transmit an electrical output to the switch 302 via the output 368. When the isolation power converter 352 is in the “OFF” state, the isolation power converter 352 is disabled. Thus, an electrical signal is not transmitted from the isolation power converter 352 to the switch 302 via the output 368.

In operation, the isolation power converter 352 is configured to operate as a DC/DC converter by modifying the input power received from the power supply 358 to a power level that is suitable to operate the switch 302. For example, the isolation power converter may transform the power level received from the power supply 358 to a reduced power level that is suitable to operate the switch 302. Moreover, the isolation power converter is also configured as an electrical isolation transformer. In operation, the isolation power converter substantially prevents any electrical spikes from damaging the switch 302 or other components in the string 220.

In a second mode of operation, an operator may desire to electrically isolate the string 220 to enable maintenance to be performed on the string or for various other reasons. To manually isolate the string 220, the operator inputs a command into the user interface 359 that instructs the processor 270 to isolate the string 220. In this case, the processor 270 transmits a command to the isolation power converter 352 to “open” or de-energize the switch 302. More specifically, in response to the command to isolate the string 220, the isolation power converter 352 is instructed to cease outputting a voltage signal on the output 368. To re-connect the string 220 to the end user, the operator inputs a command into the user interface 359 that instructs the processor 270 to reconnect the string 220 to the array. In this case, the processor 270 transmits a command to the isolation power converter 352 to “close” or energize the switch 302. More specifically, in response to the command to re-energize the string 220, the isolation power converter 352 is turned ON by processor 270 and a voltage signal is transmitted from the isolation power converter 352 to the switch 302 via the output 368. In another mode of operation, the control board 350 is configured to automatically isolate the string 220 when an electrical fault is detected in the string 220 or when the power output from the string 220 decreases below a predetermined threshold. The predetermined threshold may be determined based on the power output for other strings in the array. For example, if the substring 220 is generating less than 20% of the power that the other substrings are generating, the string 220 may have a fault, and thus is automatically isolated from the array.

For example, during operation, the switch 302 becomes forward biased when the string is not contributing as much power to the system as other strings in the array, and hence a need may exist to automatically bypass the string. Accordingly, to automatically electrically isolate the string 220, the control board 350 is configured to identify when the switch 302 is forward biased.

In the exemplary embodiment, the isolation power converter 352 is configured to determine when the FET 302 becomes forward biased by evaluating the voltage at the string. More specifically, as shown in FIG. 16, the isolation power converter 352 is enabled to receive an electrical input at the input 364 that represents the negative voltage at the string 220. Moreover, the isolation power converter 352 is enabled to receive an electrical input at the input 366 that represents the positive voltage at the string 220. During operation, the isolation power converter 352 monitors the signals received at the inputs 364 and 366 to determine when the switch 302 is forward biased. If a forward bias condition is detected, the isolation power converter 352 automatically transmits a signal to the switch 302 to open or shunt the string 220. In the exemplary embodiment, shunting the string 220 is accomplished over a relatively long duty cycle and short detection time to facilitate maximizing the benefit of transistor shunting. If the bypass condition is not detected at a new detection cycle, the transistor 302 will not be activated and the PV module is returned to its normal working condition. Therefore, during operation, the isolation power converter 352 monitors the signals received at the inputs 364 and 366 to detect the voltage across the string 220 to determine whether the switch 302 is forward biased.

The control board 350 therefore enables an operator to locally or remotely input a shutdown command to electrically isolate one string or a plurality of strings. Moreover, the power utilized to operate the switches is provided by an electrically isolated power converter that receives power from a reliable power source that is mounted on the control board 350. Optionally, the power supply 358 may be mounted on the power transfer board 32. The control board 350 utilizes a single switch or transistor to electrically isolate each string, and therefore utilizes less power than conventional devices.

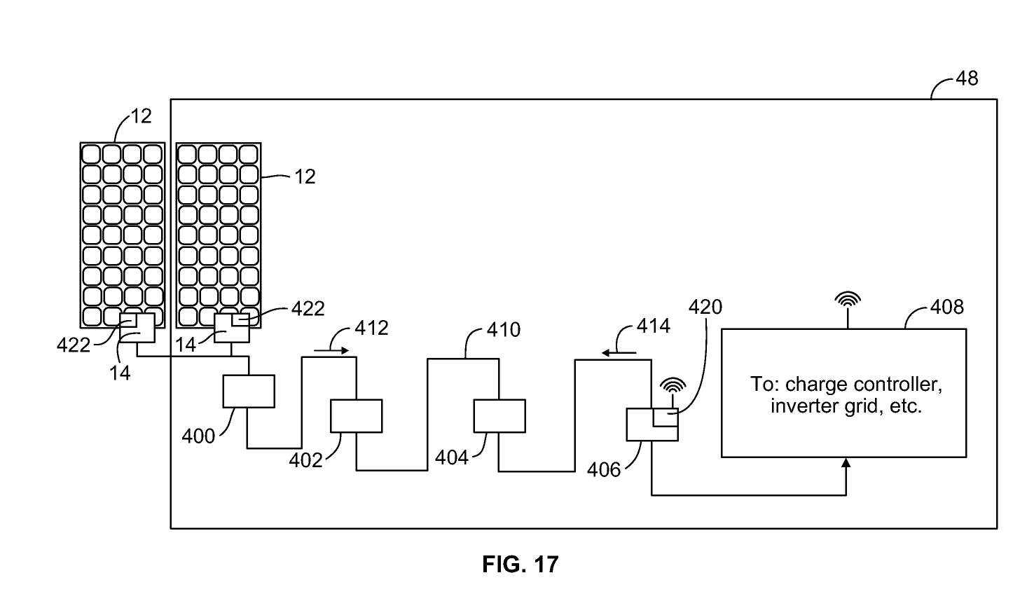

FIG. 17 illustrates an exemplary external system 48 that may include the junction box 14 and the control boards 200/300/350 described in FIGS. 1-16. In the exemplary embodiment, the system 48 represents an electrical distribution system. As discussed above, the system 48 may include, for example, a power distribution system, an electrical load, an electrical storage device, or another junction box that is coupled to another PV module.

In the exemplary embodiment, the system 48 includes at least two PV modules 12 and a junction box 14 coupled to each respective PV module 12. The junction boxes 14 may include any of the control boards described herein. Moreover, the junction box 48 may include a conventional control board. The system 48 also includes, for example, a second PV module 12, a combiner 400, a DC switch 402, a ground-fault circuit interrupter (GFCI) 404, a safety isolation device 406 and an end user 408. As shown in FIG. 17, the outputs from the PV modules 12 are electrically coupled to the input of the combiner 400. The combiner 400 combines the voltages from the PV module and conveys a single power signal to the DC switch 402. The DC switch 402 is a manually operated switch that is operable to interrupt the power signal being transmitted from the PV modules 12 to the end user 408. The power signal is then transmitted through the GFCI 404 and the safety isolation device 406 to the end user 408. As shown in FIG. 17, the two PV modules 12, the combiner 400, the DC switch 402, the ground-fault circuit interrupter (GFCI) 404, the safety isolation device 406 and the end user 408 are all electrically coupled together using a power line 410.

As discussed above, PV modules, such as PV modules 12, generate power when exposed to light even when the PV modules 12 are not coupled to an electrical grid. The power generated by the PV modules 12 may pose a safety hazard for personnel repairing the PV modules 12. Therefore, the safety isolation device 406 is configured to provide an active safety circuit that works in conjunction with the DC switch 402. In the exemplary embodiment, the safety isolation device 406 is located remotely from the PV modules 12, for example, in a person's home or basement. Optionally, the safety isolation device 406 may be incorporated into the DC switch 402.

In one specific embodiment, the safety isolation device 406 is configured to generate a radio frequency (RF) communication signal 414 that is transmitted wirelessly from the safety isolation device 406 to the junction box 14 to control the operation of the PV module 12. Therefore, the safety isolation device 406 includes a transmitter 420 that transmits the wireless signal to the junction box 14. The junction box 14 includes a transceiver 422 that receives the wireless communication. In the exemplary embodiment, the safety isolation device 406 is configured to generate a communication signal 414 that is transmitted over the power line 410 to the junction box 14 to control the operation of the PV module 12. In operation, the communication signal 414 is overlayed onto the power signal 412. Therefore, the communication signal 414 has a frequency or harmonic that is different than the frequency of the power signal 412 such that the communication signal 414 does not interfere with the power signal 412.

In operation, the safety isolation device 406 actuates the relays shown in FIGS. 9-14 to enable the PV module 12 to transition from an operational state, wherein the PV module 12 is delivering power to the end user 408, to the safe state wherein the PV module 12 is electrically isolated from the end user 408. In one mode of operation, the safety isolation device 406 automatically generates and transmits an “ON” communication signal 414 to the PV module 12. The “ON” communication signal 414 is utilized by the junction box 14 to configure the three-stage relay 260 for normal operation, e.g. power is delivered from the PV module 12 to the end user 408. In a second mode of operation, the “ON” signal is interrupted such that the “ON” signal is not transmitted to the PV module 12. For example, the “ON” signal may be interrupted when an operator manually opens the DC switch 402. The “ON” signal may be interrupted when the GFCI device 404 trips, etc. In either case, when the PV module 12 fails to receive the “ON” signal, the PV module 12 automatically isolates the PV module 12 from the system 48. In the exemplary embodiment, the junction box 14 configures the three-stage relay 260 for safe state operation in which no power is delivered from the PV module 12 to the end user 408. Accordingly, if the communication signal 414 is disrupted for any reason, the PV module 12 automatically realigns for safe state operation.

PV modules may have a variable electricity generation efficiency that is caused by manufacturing and/or installation conditions. In addition, individual PV modules may also have varying efficiency due to aging. To maximize the efficiency of the PV array it is desirable that each PV module, or group of PV modules, has a predictable and constant electrical characteristic output characteristic over its useful life. More specifically, each of the PV modules has a maximum power point (MPP) that identifies the optimal operating point of the PV module. However, when multiple PV modules are connected in series to form the PV array, if one PV module generates less power, and thus is operating under the MPP of the PV array, then the PV module generating less power determines the current flow through the PV array. Accordingly, the weakest PV module in the PV array drives the PV array such that the PV array is not generating the maximum power.

According to another specific embodiment of the invention, the control board 34 of junction box 14 is configured to utilize a power converter to adjust an output from the PV module to which the junction box is coupled to substantially match the MPP for the PV array.

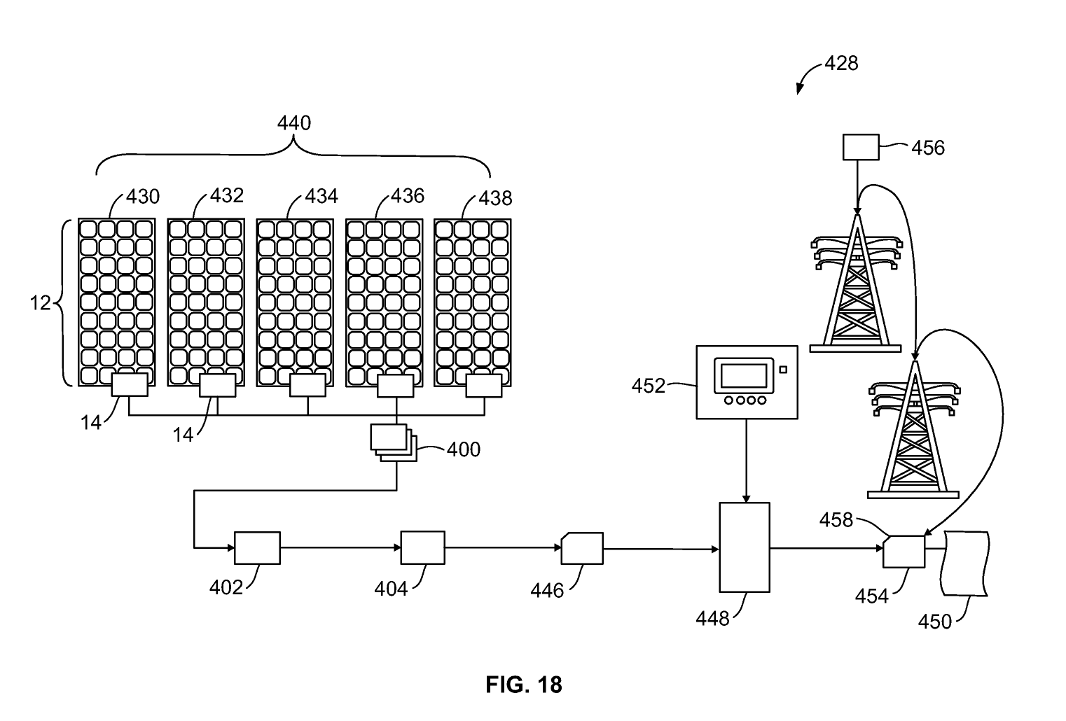

FIG. 18 illustrates an exemplary external system 428 that may include the junction box 14 and the control boards 200/300/350 described in FIGS. 1-16. In the exemplary embodiment, the system 200 represents an electrical distribution system. The system 428 includes a plurality of PV modules 12 and a junction box 14 coupled to each respective PV module 12. For example, the system 428 may include a PV module 430, a PV module 432, a PV module 434, a PV module 436, and a PV module 438. Each of the PV modules 430, 432, 434, 436, and 438, has a junction box 14 coupled to it. In the exemplary embodiment, the PV modules 430, 432, 434, 436, and 438 are electrically coupled together in series to form a PV module array 440, or simply an array 440. It should be realized that although the exemplary system 428 is shown as including five PV modules, the system 200 may include any number of PV modules electrically coupled together to form the array 440.

The system 428 also includes, for example, a combiner 400, a DC switch 402, a ground-fault circuit interrupter (GFCI) 404, a battery charge controller/monitor device 446, and an inverter 448. As shown in FIG. 18, the outputs from the array 440 are electrically coupled to the input of the combiner 400. The combiner 400 combines the voltages from all the PV modules 12 and conveys a single power signal to the DC switch 402. The DC switch 402 is a manually operated switch that is operable to interrupt the power signal being transmitted from the array 440 to an end user 450. The power signal is then transmitted through the GFCI 404, the battery charge controller 446, via the inverter 448, to the end user 450. The end user 450 may be a business or home. Accordingly, in the exemplary embodiment, the inverter 448 converts the DC power generated by the array 440 to AC power that is usable by the end user 450. The end user 450 may view and/or control the operation of the system 428 on a display 252. The system 428 may also include an automatic meter reading device 454 that is mounted proximate to the home. The device 454 is configured to transmit a signal to a remote location 456 that represents the AC power consumed by the end user 450. The device 454 may also be configured to transmit other information generated by the PV array 440 to the remote location 456. In one embodiment, the system 428 is configured to generate a radio frequency (RF) communication signal that is transmitted wirelessly from the device 454 to remote location 456. Therefore, the device 454 includes a transmitter 458 that transmits the wireless signal to the remote location 456.

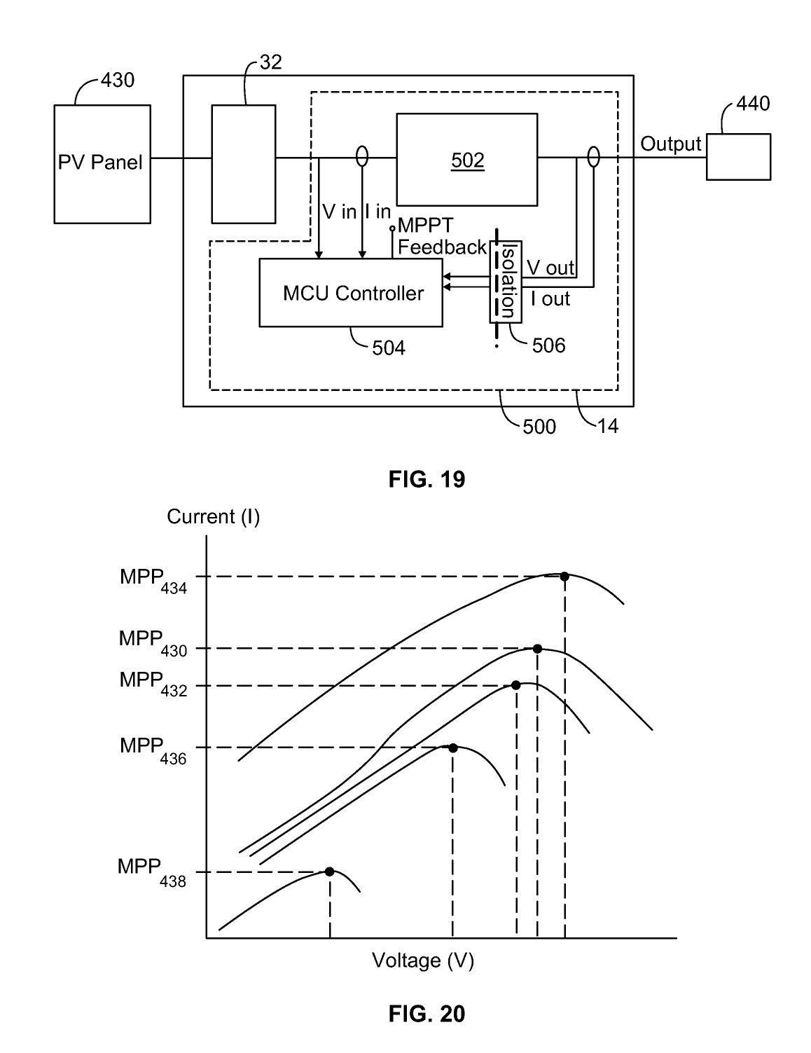

FIG. 19 is a simplified block diagram of an exemplary control board 500 that may be used with the system 428 shown in FIG. 18. For example, the control board 500 may be installed in any of the PV modules 430, 432, 434, 436, and 438 shown in FIG. 18. In the exemplary embodiment, the control board 500 is substantially similar in construction to the control board 34 described above. The control board 500 is configured to be coupled to the power transfer structure or board 32 shown in FIG. 2. Accordingly, the control board 500 is a PCB that includes a plurality of mating connectors (not shown) that is equal to the quantity of transfer interfaces 140 installed on the transfer structure or board 32. The combination of the transfer interfaces 140 (shown in FIG. 2) and the mating connectors 160 on the control board 500 enable the outputs from the foil connectors 110, on the power transfer board 32 (or conductive connectors on the power transfer structure), to be conveyed to the control board 500 via the transfer interfaces 140 and the mating connectors as discussed above.

To further explain the operation of the control board 500, the exemplary embodiment illustrates the control board 500 being installed in the junction box 14 of the PV module 430. However, it should be realized that each PV module in the array 440 includes an associated junction box 14 wherein the control board 500 may be installed in each respective junction box 14. The control board 500 includes a power converter 502, a processor 504 that is coupled to the power converter 502, and an electrical isolation device 506 that is configured to electrically isolate the signals transmitted between the processor 504 and the array 440. As used herein the term “processor” may include any processor or processor-based system including, for example, reduced instruction set circuits (RISC), application specific integrated circuits (ASICs), logic circuits, and any other circuit or processor capable of executing the functions described herein. The processor 504 is configured to control the operation of the control board 500, including the power converter 502 to execute instructions and to process information received from the PV module 430 and the array 440. The processor 504 may also include signal processing circuitry, based on a general purpose or application-specific computer, associated memory circuitry for storing programs and routines executed by the computer, as well as configuration parameters and image data, interface circuits, and so forth.

As shown in FIG. 19, the processor 504 receives the electrical output from the PV module 430. The processor 504 identifies the MPP for the PV module 430. For example, during operation, there is one ideal voltage/current (V/C) pair that enables the PV module 430 to generate the maximum power, e.g. the maximum power point (MPP). However, because the PV module 430 is coupled in series with other PV modules, e.g. 432, 434, 436, and 438, the PV module having the lowest MPP, e.g. the PV module 438, drives the array 440. More specifically, the array 440 generates a current that is approximately equal to the current generated by the PV module in the array 440 generating the lowest current flow.

For example, FIG. 12 is a graphical illustration of exemplary MPP's that may be generated by each of the PV modules 430, 432, 434, 436, and 438. MPP₄₃₀ represents the maximum power generated by the PV module 430, MPP₄₃₂ represents the maximum power generated by the PV module 432, MPP₄₃₄ represents the maximum power generated by the PV module 434, MPP₄₃₆ represents the maximum power generated by the PV module 436, and MPP₄₃₈ represents the maximum power generated by the PV module 438. As shown in FIG. 12, the PV module having the highest MPP is PV module 434. The PV module having the lowest MPP is PV module 438. Accordingly, the processor 504 is configured to determine the MPP for each PV module in the array 440. Based on the determined MPP's, the processor 504 is configured to select one MPP, such as MPP₄₃₄, that will enable the overall array 440 to operate at the maximum power. Optionally, the processor 504 may analyze the MPP's for each PV module and select an optimal MPP for the array 440 that is different than each of the MPP's for each PV module. The processor 504 is then configured to operate the power converter 502 to modify the V/C pair received from the PV module 430 to a different V/C pair that is based on the determined MPP for the array 440. More specifically, once the processor 504 has determined the MPP for the array 440, the V/C pair input to the power converter 502 is transformed into the V/C pair that achieves the MPP for the array. For example, assuming that the V/C pair input to the power converter 502 for PV module 430 is 30 Volts/5 Amps (overall power is 150 Watts), and the processor 504 has determined that the MPP for the system is achieved when the current flow through the array 440 is 10 Amps (e.g. the same as generated by the PV module 434). The processor 504 will operate the power converter 502 to modify the V/C pair input to the PV module 430 (30 Volts/5 Amps) to 15 Volts/10 Amps such that the current output from the PV module 430 is substantially equal to the current generated by the PV module 434 without modifying the power output from the PV module 430. In this manner, the V/C pairs for each PV module in the array 440 may be modified by a respective power converter 502 to enable the array 440 to achieve overall maximum power, i.e. to enable the array 440 to operate at its MPP and maximum efficiency while also enabling each PV module in the array 440 to operate at its own MPP and maximum efficiency. The power converter 502 may be implemented as a DC-DC power supply such as a buck, a boost, or a buck-boost power supply. Additionally, the power converter 502 may be implemented as a DC-DC transformer, for example.

In the exemplary embodiment, the MPP for the array 440 (MPP_{Array}) is determined by querying each individual PV module in the array 440 to identify the MPP for each individual PV module in the array 440. In one embodiment, the individual PV module MPP's are then used to select the MPP_{Array}. In another embodiment, the MPP for the inverter 448 may be utilized to modify the MPP's for the individual PV modules to optimize the performance of the array 440. For example, the impedance of the inverter 448 may be modified to achieve the MPP_{Array}. Once the MPP_{Array} is selected, the power converter 502 is utilized to modify the V/C pair output from each PV module to substantially match the MPP_{Array}.

The control board 500 described above, may be installed in the junction box 14 during installation of the array 440. Optionally, the control board 500 may be integrated into the array 440 after the array 440 is installed. The control board 500 may be used in conjunction with a centralized inverter, (such as inverter 448) to provide communication on the ‘state of the PV module’ as needed. The PV modules discussed herein may also be modified to include safety features such as a PV module shut-off device that enables an operator to electrically disconnect a PV module from the array. Electrical surge protection from faults such as improper installation or lightning effects may also be included.

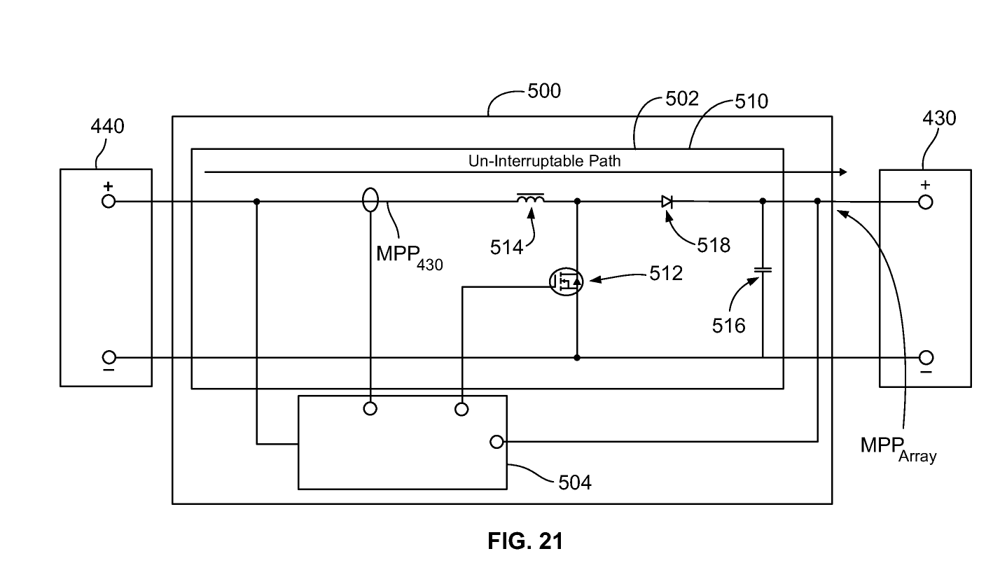

FIG. 21 is a simplified electrical schematic illustration of a portion of the control board 500 shown in FIG. 18. As discussed above, the V/C pairs for at least some of the PV modules in the array 440 are modified to achieve an overall maximum power for the array 440. To modify the V/C pairs output from the PV modules, the control board 500 utilizes the power converter 502. As shown in FIG. 21, in one embodiment, the power converter 502 may be implemented as a DC-DC converter 510. The DC-DC converter 510 includes a switching device, such as a Field Effect Transistor (FET) 512, an inductor 514, and a capacitor 516. The inductor 514 is coupled in electrical series with the FET 512 and the capacitor 516 is coupled in parallel with the FET 512. The DC-DC converter 510 may also include a diode 518.

In one mode of operation, the DC-DC converter 510 modifies the V/C pair output from the PV module (MPP₄₃₀) to a V/C pair (MPP_{Array}) that optimizes the overall power and efficiency of the array 440 as discussed above. To modify the V/C pair MPP₄₃₀, the processor 504 first selects or identifies the MPP_{Array} as discussed above. The processor 504 then operates the FET 512 to convert the V/C pair MPP₄₃₀ to the V/C pair MPP_{Array}. More specifically, the processor 504 transmits a signal, at a predetermined frequency, to the FET 512 that causes the FET 512 to oscillate at the predetermined frequency. Oscillating the FET 512 at the predetermined frequency causes the voltage of the V/C pair MPP₄₃₀ to be transformed to the selected voltage of the V/C pair MPP_{Array}. Moreover, excess energy is stored in the inductor 514 and the capacitor 516. In the exemplary embodiment, the FET 512 may be oscillated at a plurality of frequencies, wherein each frequency corresponds to a different voltage being output from the DC-DC converter 510.

In the exemplary embodiment, the DC-DC converter 510 is also operable to electrically isolate the PV module 430 from the array 440. Such electrical isolation may be required, for example, when an electrical fault has occurred in the PV module 430. To electrically isolate the PV module 430 from the array 440, the processor 504 is configured to turn off the FET 512. In this case, when the FET 512 does not receive an appropriate signal from the processor 504, the FET 512 is off and defaults to an “open” position. As shown in FIG. 21, when the FET 512 is in the open position, current discharged from the PV module 430 is channeled across the top rail through the inductor 514, through the FET 512 and back through the bottom rail to the PV module 430. As such, when the FET 512 is in the open position, current is channeled in a loop within the control board 500 and is not supplied to the array 440. Accordingly, in one embodiment, the DC-DC converter 510 is also configured to function as an isolation transformer between the PV module 430 and the array 440 to fully electrically isolate the PV module 430 from the array 440. Specifically, once the processor 504 is configured to turn on the FET 512, the DC-DC converter 510 will not allow power to be transmitted from the PV module 430 to the array 440, because when the DC-DC converter 510 is operating as an isolation transformer, only AC power is enabled to be transmitted through the isolation transformer.

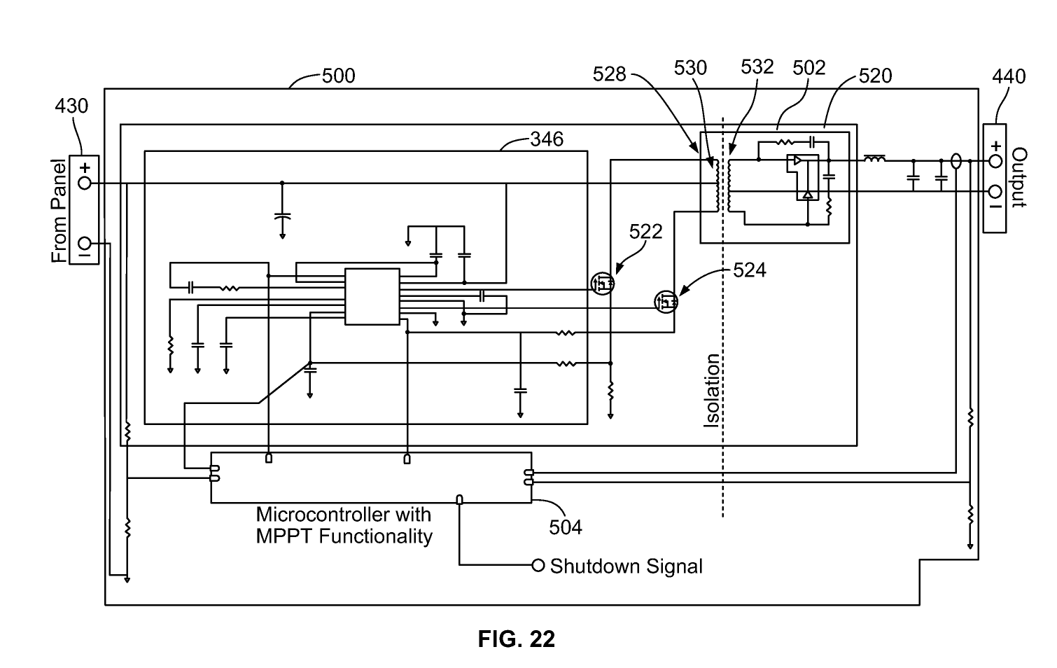

FIG. 22 is another simplified electrical schematic illustration of a portion of the control board 500 shown in FIG. 18. As shown in FIG. 22, in one embodiment, the power converter 502 may be implemented as a DC-DC converter 520. The DC-DC converter 520 includes a first switching device, such as FET 522 and a second switching device, such as FET 524. The DC-DC converter 520 also includes a DC-DC driver 526 that is electrically coupled to, and operates, the FETs 522 and 524 based on a signal received from the processor 504. The DC-DC converter 520 also includes an isolation transformer 528 that is coupled to the outputs of each respective FET, e.g. FETs 522 and 524.

In one mode of operation, the DC-DC converter 520 is configured to modify the V/C pair output from the PV module (MPP₄₃₀) to a V/C pair (MPP_{Array}) that optimizes the overall power and efficiency of the array 440 as discussed above. To modify the V/C pair MPP₄₃₀, the processor 504 first selects or identifies the MPP_{Array} as discussed above. The processor 504 then transmits a signal to the driver 526. The driver 526 includes electrical circuitry to enable the signal received from the processor 504 to be converted to a pair of signals. Each signal in the pair of signals is transmitted to a respective FET to operate the FET. More specifically, the processor 504 transmits a signal to the driver 526.

During operation, when the processor 504 determines that power should be supplied from the PV module 430 to the array 440, the driver 526 transmits a signal at the predetermined frequency to the FETs 522 and 524 that causes the FETs 522 and 524 to oscillate at the predetermined frequency. Oscillating the FETs 522 and 524 at the predetermined frequency causes the V/C pair MPP₄₃₀ to be transformed to the selected V/C pair MPP_{Array}. Moreover, excess energy is stored in the inductors and the capacitors shown in FIG. 22. The FETs 522 and 524 may be oscillated at a plurality of frequencies, wherein each frequency corresponds to a different voltage being output from the DC-DC converter 520.

Additionally, the oscillation of the FET's at the predetermined frequency causes the voltage signal output from the FET's to be converted to an A/C signal which is then transmitted through the transformer 528. More specifically, as shown in FIG. 22, when the FETs 522 and 524 are energized, an AC signal is transmitted from the FET 522 through the primary winding 530 of the transformer 528 and discharged through the FET 524. The secondary winding 532 then transmits the electrical signal generated by the windings to the array 440.

In the exemplary embodiment, the DC-DC converter 520 is also operable to electrically isolate the PV module 430 from the array 440. Such electrical isolation may be required, for example, when an electrical fault has occurred in the PV module 430. To electrically isolate the PV module 430 from the array 440, the processor 504 is configured to cease transmitting a signal to the driver 526. The driver 526 then ceases to transmit a corresponding signal to the FETs 522 and 524. In this case, when either the FET 522 or the FET 524 does not receive a signal from the processor 504, the FETs 522 and 524 are off and default to an “open” position. As shown in FIG. 22, when either the FET 522 or the FET 524 is in the open position, current discharged from the PV module 430 is channeled through the FET 522. However, because the FET's 522 and 524 are open, the output from the FETs 522 is a DC voltage signal. Thus, the isolation transformer 528 is unable to generate an output based on a DC voltage input, thus effectively isolating the PV module 430 from the array 440.

The control boards described herein utilize transformer-based DC-DC circuitry to implement efficiency improvements on the PV modules or a sub-set of the PV modules. The control boards also provide an effective device for electrically isolating the PV module from the array. It should be realized that a plurality of electrical designs to implement a DC-DC converter may be utilized, and that the embodiments described herein are exemplary embodiments. Specifically, the junction box described herein includes a control board that enables the control board to electrically isolate the PV module from the array. Moreover, the control boards optimize the output from each PV module to optimize the power generated, and the efficiency of, the array.

While this invention has been described as having an exemplary design, the present invention may be further modified within the spirit and scope of this disclosure. The application is, therefore, intended to cover any variations, uses, or adaptations of the invention using its general principles. Further, this application is intended to cover such departures from the present disclosure as come within known or customary practice in the art to which this invention pertains.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A junction box for electrically connecting a photovoltaic (PV) module to a power distribution system, the PV module having a plurality of conductors for electrically connecting the PV module to the junction box, said junction box comprising:
a housing having a mounting side configured to be mounted on the PV module;
a power transfer structure mounted within the housing, the power transfer structure including a plurality of conductive connectors and a transfer interface, wherein each of said plurality of conductive connectors forms an electrical interface to the PV module and wherein said transfer interface couples the junction box to said power distribution system; and
a user-removable control board mounted within the housing, wherein said power transfer structure interfaces with said control board to convey power from the PV module to the control board via the power transfer structure.

2. A junction box in accordance with claim 1 wherein said power transfer structure comprises a power transfer board, said conductive connectors comprise foil connectors each of which has a foil receptacle and foil output, the foil receptacle configured to receive and electrically connect to a corresponding foil conductor, and said transfer interface has transfer inputs and transfer outputs, at least one transfer input being electrically coupled to a respective foil connector output, and said control board including a mating connector configured to mate with the transfer interface.

3. A junction box in accordance with claim 2, wherein the mating connector is configured to engage and disengage from the transfer interface separate and independent from the electrical connection of the foil conductor to the foil receptacle.

4. A junction box in accordance with claim 1 further comprising a pair of system connectors, each of the system connectors having an input and an output, the system connector inputs configured to mate with a respective mating connector of the power distribution system, the system connector outputs being configured to electrical couple to the transfer interface.

5. A junction box in accordance with claim 1 further comprising a pair of guides coupled to the power transfer structure, the pair of guides configured to align the transfer interface with the mating connector.

6. A junction box in accordance with claim 1 further comprising a cover configured to couple to the control board, the cover being fabricated from an electrically insulating, thermally conductive material to dissipate heat generated by the control board.

7. A junction box in accordance with claim 1 wherein the control board comprises a shut-off circuit operable to interrupt power transfer between the PV module and the power transfer structure.

8. A junction box in accordance with claim 7 wherein the shut-off circuit comprises a first FET or other semiconductor switch and a second FET or other semiconductor switch, the first switch being configured to short circuit the PV module, the second switch being configured to electrically bypass the PV module.

9. A junction box in accordance with claim 7 wherein the shut-off circuit comprises a three-stage FET or semiconductor switch, a first stage of the three-stage semiconductor switch configured to be in a closed position when a second stage of the three-stage semiconductor switch is in an open position.

10. A junction box in accordance with claim 7 wherein the shut-off circuit comprises a pair of electrical/mechanical relays.

11. A junction box in accordance with claim 1 wherein the PV module comprises a plurality of substrings, the junction box further comprising a transistor coupled to at least one of the substrings, the transistor configured to electrically isolate the substring based on a signal received from a remote location.

12. A junction box in accordance with claim 11 further comprising an isolation power converter coupled to the transistor, the isolation power converter configured to operate the transistor based on a user input.

13. A junction box in accordance with claim 11 further comprising an isolation power converter coupled to the transistor, the isolation power converter configured to monitor the power output from at least one of the substrings and automatically isolate the substring when a power output from the substring decreases below a predetermined threshold.

14. A junction box in accordance with claim 11 further comprising an isolation power converter coupled to the transistor, the isolation power converter configured to receive electrical power from a power supply that is mounted on at least one of the control board and the power transfer board.

15. A junction box in accordance with claim 11 further comprising:
an isolation power converter coupled to the transistor, the isolation power converter configured to open and close the transistor; and
a processor coupled to the isolation power converter, the processor configured to activate and deactivate the isolation power converter based on a signal received from a user.

16. A junction box in accordance with claim 11 further comprising an isolation power converter coupled to the transistor, the isolation power converter including a DC/DC converter configured to receive electrical power from a power supply and transform the electrical power to a power level to operate the transistor.

17. A junction box in accordance with claim 1 wherein the PV module is electrically coupled to an end user utilizing a power line, the junction box further configured to receive a communication signal from a safety isolation device over the power line and control the operation of the PV module based on the communication signal.

18. A junction box in accordance with claim 1 wherein the control board is configured to receive an input from a PV array, to determine a maximum power point (MPP) based on the received input, and to utilize a power converter to adjust an output from the PV module to substantially match the MPP for the PV array.

19. A junction box in accordance with claim 18 wherein the power converter comprises a pair of field effect transistors (FETs), the pair of FETs being operable in a first configuration to transmit an electrical signal through an isolation transformer, and operable in a second configuration to electrically isolate the PV module from the PV array.

20. A junction box in accordance with claim 18 further comprising a cover configured to couple to the control board, the cover being fabricated from a thermally conductive material to dissipate heat generated by the control board.

21. An electrical isolation device for coupling to at least one PV module, said device comprising:
a junction box; and
a safety isolation device coupled to the junction box, the safety isolation device configured to transmit a communication signal to the junction box, the junction box configured to operate the PV module in a first or second mode based on the communication signal.

22. An electrical isolation device in accordance with claim 21 wherein the electrical isolation device is configured to transmit said communication signal over a power line.

23. An electrical isolation device in accordance with claim 21 wherein the electrical isolation device is configured to wirelessly transmit said communication signal.

24. An electrical isolation device in accordance with claim 21 wherein the junction box further comprises a three-stage relay configured to electrically isolate the PV module when the communication signal is interrupted.
